(19) United States
(12) Patent Application Publication
(10) Pub. No.: US 2026/0305391 A1
(43) Pub. Date: Oct. 1, 2026

(54) PACKAGE SUBSTRATE WITH A MOLD EXTENSION AND Z-HEIGHT RESET LAYER

(71) Applicant: Intel Corporation, Santa Clara, CA (US)

(72) Inventors: Debendra MALLIK, Chandler, AZ (US); Rahul N. MANEPALLI, Chandler, AZ (US); Sairam AGRAHARAM, Chandler, AZ (US)

(21) Appl. No.: 19/093,636

(22) Filed: Mar. 28, 2025

(51) Int. Cl. H10W 70/60; H10W 70/05; H10W 70/63; H10W 70/65; H10W 70/692; H10W 74/01; H10W 90/00

(52) U.S. Cl. CPC H10W 70/611; H10W 70/095; H10W 70/635; H10W 70/65; H10W 70/692; H10W 74/016; H10W 90/00; H10W 90/724

(57) ABSTRACT

Embodiments disclosed herein include an apparatus that includes a substrate with a first surface and a second surface opposite from the first surface. In an embodiment, a first pillar is on the first surface of the substrate, and a second pillar is on the first surface of the substrate. In an embodiment, a first layer is over the first surface of the substrate, and the first layer embeds the first pillar and the second pillar. In an embodiment, a third pillar is on the second pillar, and a component is over the first layer. In an embodiment, the component is coupled to the second pillar. In an embodiment, a second layer is over the first layer, where the second layer embeds the third pillar and the component.

### BACKGROUND

High performance computing is driving the adoption of bigger die complexes on a single substrate. As a result, the overall package form factor increases, and this can lead to higher substrate warpages. The high warpage causes yield loss during surface mount technology (SMT) for ball grid array (BGA) packages and/or requires high compression pressure and expensive retention mechanisms for lang grid array (LGA) packages.

Further, there is significant demand for advanced packaging with high bandwidth and high density interconnects for heterogenous chiplet integration. For example, in the case of graphics processing unit (GPU) and high bandwidth memory (HBM) based accelerator technologies, there is also need for very large chip complexes on the package. Existing packaging solutions for such technologies have some drawbacks. For example, the dielectric stack-up thickness variation and topography across a substrate panel creates issues with respect to the interconnects between layers in the Z-direction. Typically, higher solder volumes (e.g., larger bump critical dimensions (CDs)) are used to account for thickness variation. This prevents the scaling of bump pitch to smaller dimensions that are needed for high bandwidth solutions. In some instances X-Y positional accuracy is also limited.

### BRIEF DESCRIPTION OF THE DRAWINGS

FIG. 1 is a cross-sectional illustration of an electronic system with a warped package substrate, in accordance with an embodiment.

FIG. 2A is a cross-sectional illustration of an electronic system with a warpage reset layer for an LGA packaging solution, in accordance with an embodiment.

FIG. 2B is a cross-sectional illustration of an electronic system with a warpage reset layer for a BGA packaging solution, in accordance with an embodiment.

FIGS. 3A – 3C are schematic illustrations that depict improved capacitance performance for some embodiments described in greater detail herein.

FIGS. 4A – 4G are cross-sectional illustrations that depict a process flow for forming a package substrate with a warpage reset layer, in accordance with an embodiment.

FIG. 4H is a flow diagram that depicts a process for forming a package substrate with a warpage reset layer, in accordance with an embodiment.

FIGS. 5A and 5B are cross-sectional illustrations that depict interconnect architectures for electronic systems, in accordance with an embodiment.

FIG. 6A is a cross-sectional illustration of a package substrate with a mold extension layer for improved interconnect scaling, in accordance with an embodiment.

FIG. 6B is a cross-sectional illustration of a package substrate with a mold extension layer for improved interconnect scaling, in accordance with an additional embodiment.

FIGS. 7A – 7H are cross-sectional illustrations that depict a process flow for forming a package substrate with a mold extension layer, in accordance with an embodiment.

FIG. 7I is a flow diagram that depicts a process for forming a package substrate with a mold extension layer, in accordance with an embodiment.

FIGS. 8A – 8I are cross-sectional illustrations that depict a process flow for forming a package substrate with a mold extension layer on a top surface and a bottom surface of the package substrate, in accordance with an embodiment.

FIG. 8J is a flow diagram that depicts a process for forming a package substrate with an upper and lower mold extension layer, in accordance with an embodiment.

FIGS. 9A – 9H are cross-sectional illustrations that depict a process for forming a package substrate with a mold extension layer and a Z-height reset layer, in accordance with an embodiment.

FIG. 9I is a process flow diagram that depicts a process for forming a package substrate with a mold extension layer and a Z-height reset layer, in accordance with an embodiment.

FIG. 10 is a cross-sectional illustration of an electronic system that comprises a package-to-package connection with package substrates that comprise a Z-height reset layer, in accordance with an embodiment.

FIGS. 11A – 11D are cross-sectional illustrations that depict a process for forming a package substrate with a Z-height reset layer and aligned second level interconnect pads, in accordance with an embodiment.

FIG. 11E is a process flow diagram that depicts a process for forming a package substrate with a Z-height reset layer and aligned second level interconnect pads, in accordance with an embodiment.

FIGS. 12A – 12H are cross-sectional illustrations that depict a process for forming an electronic system with a package substrate that comprises a mold extension layer and a die encapsulation layer, in accordance with an embodiment.

FIG. 12I is a process flow diagram that depicts a process for forming an electronic system with a package substrate that comprises a mold extension layer and a die encapsulation layer, in accordance with an embodiment.

FIG. 13 is a plan view illustration of a substrate with a panel substrate that may be used to fabricate a plurality of devices, such as any of the electronic systems and/or package substrates described in greater detail herein.

FIG. 14 is a cross-sectional illustration of an electronic system with a package substrate coupled to a board, in accordance with an embodiment described in greater detail herein.

FIG. 15 is a schematic of a computing device built in accordance with an embodiment.

### EMBODIMENTS OF THE PRESENT DISCLOSURE

Described herein are processes and structures to improve warpage and positional variations on substrates to enable enhanced pitch scaling, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, the drive to larger form factor package assemblies for advanced computing has led to issues with warpage and alignment of interconnect pads in the X, Y, and/or Z planes. The offsets driven by such issues limits the ability to continue scaling interconnect densities. Accordingly, data bandwidths between dies on package assembly and/or data bandwidths between different package assemblies are limited. Therefore, embodiments disclosed herein provide different package manufacturing assembly processes and/or features that allow for continued scaling of interconnect densities and/or mitigation for substrate warpage. In the embodiments disclosed herein, the process flows largely focus on a single device and/or unit. However, it is to be appreciated that the process flows may be implemented at any form factor size, such as a panel substrate form factor, a quarter panel form factor and/or the like. Though, process flows may also be implemented on single device and/or unit form factors as well. In the case of larger form factor substrates (e.g., a panel or a quarter panel), the individual devices and/or units may be fabricated substantially in parallel.

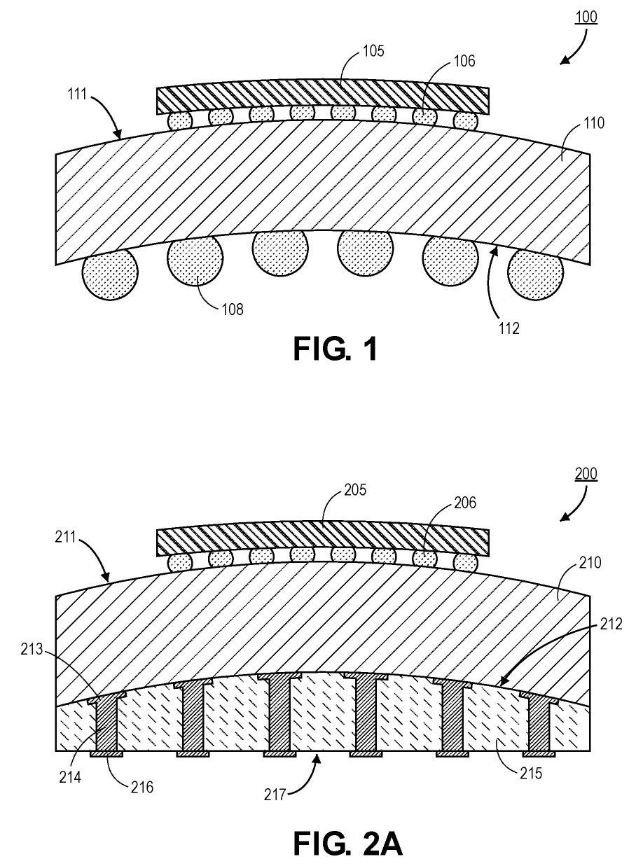

Referring now to FIG. 1, a cross-sectional illustration of an electronic package 100 is shown, in accordance with an embodiment. In an embodiment, the electronic package 100 comprises a package substrate 110 and a die 105 that is coupled to a first surface 111 of the package substrate 110. For example, the die 105 may be coupled to the package substrate 110 by interconnects 106, such as any suitable first level interconnect (FLI) architecture (e.g., solder balls, copper bumps, hybrid bonding, and/or the like). In an embodiment, interconnects 108 may be coupled to a second surface 112 of the package substrate 110. The interconnects 108 may comprise any suitable second level interconnect (SLI), such as a ball grid array (BGA), a land grid array (LGA), or the like.

The package substrate 110 may comprise any suitable package substrate structure, such as a core (e.g., a glass core or an organic core) with organic dielectric layers formed over and/or under the core. In an embodiment, the die 105 may comprise any type of die, such as a processor (e.g., a central processing unit (CPU), a graphics processing unit (GPU), an XPU, or the like), a memory die (e.g., a HBM), a communications die, or the like. While a single die 105 is shown in FIG. 1, it is to be appreciated that any number of dies 105 may be coupled to the package substrate 110.

As shown, the package substrate 110 may experience significant warpage, as indicated by the curved first surface 111 and the curved second surface 112. The warpage may be the result of coefficient of thermal expansion (CTE) mismatches between the die 105 and the package substrate 110. That is, the warpage may be present after the die is coupled to the package substrate 110. The warpage of the second surface 112 is particularly problematic with respect to the mounting of the interconnects 108. As the warpage increases, the solder volume must be increased to accommodate the different heights between the second surface 112 and a board (not shown) that is below the package substrate 110. This increases the critical dimension (CD) of the interconnects 108, and prevents the pitch scaling that is desired to allow for higher data transfer bandwidths.

Significant electronic package design and/or materials changes have been proposed to mitigate the warpage. For example, increasing a thickness of the core of the package substrate 110, improving package substrate 110 core stiffness (e.g., through the use of glass cores), and/or adding a stiffener and/or lid are some options to reduce the warpages. However, there are a lot of assembly and reliability challenges associated with such changes. From BGA and surface mount technology (SMT) point of view, low temperature solder (LTS) and multi-ball technology are additional options to mitigate the warpage risk. However, LTS typically has lower IMAX capability, which limits the use of such interconnects in high performance computing (HPC) applications, such as those described herein. Multi-ball technology is limited in the ability to overcome high warpage. Furthermore, both of these options face significant challenges at finer SLI pitch, which limits their scalability. For LGA packages, higher compression forces can theoretically overcome the warpage challenges. However, the load mechanism becomes very complicated and expensive as the compression force requirement becomes higher. As the pin count continues to increase, the massive force required to overcome the warpage may not be practical.

Accordingly, embodiments disclosed herein may include the addition of a warpage reset layer at the second surface of the package substrate. That is, a warpage reset layer may be provided between the package substrate and an underlying board. In such a configuration, the board sees as substantially flat surface during assembly. This reduces the need to alter the mounting conditions and also allows for continued scaling of interconnect pitch to meet desired design goals. As used herein, “substantially flat” may refer to a maximum Z-height variation that is approximately 20µm or less, approximately 10µm or less, or approximately 5µm or less.

In an embodiment, the warpage reset layer may comprise a plurality of metal vias (which may sometimes be referred to herein as pillars) with a mold layer around the pillars. The mold layer is formed to a thickness that fully embeds the pillars. Thereafter the mold layer (and portions of one or more of the pillars) may be polished back to expose the pillars. In the case of an LGA package substrate, the polished surface of the mold layer may be substantially flat around room temperature since the LGA mounting is typically not done at an elevated temperature. In the case of a BGA package substrate, the polished surface may have a curvature around room temperature since the BGA mounting is done at a relatively high temperature. At the high temperature of the BGA mounting, the surface of the mold layer may be substantially flat.

In an embodiment, the substantially flat surface of the warpage reduction layer provides performance improvement and cost reduction opportunities compared to existing solutions. For example, LGA solutions may allow for shorter LGA pins, smaller LGA pads, and/or lower compression force requirements. Additionally, other room temp attachable/separable SLI technology, such as liquid metal carrier array, may benefit from the production of a substantially flat substrate. For BGA solutions, higher temperature solders can be used, the volume of the solder ball can be reduced, and the pitch between solder bumps can be decreased.

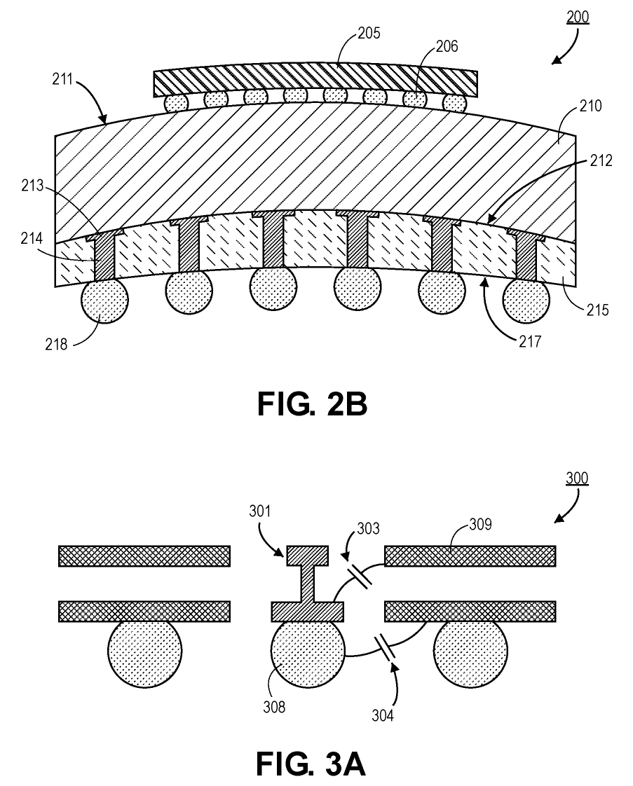

Referring now to FIG. 2A, a cross-sectional illustration of an electronic package 200 is shown, in accordance with an embodiment. In an embodiment, the electronic package 200 may comprise a package substrate 210 with a first surface 211 and a second surface 212. In an embodiment, a die 205 may be electrically coupled to the first surface 211 of the package substrate 210 by interconnects 206. In an embodiment, the first surface 211 and the second surface 212 may be curved due to warpage induced by the CTE mismatch between the die 205 and the package substrate 210. In an embodiment, the die 205, the interconnects 206, and the package substrate 210 may be similar to corresponding features described in greater detail herein with respect to FIG. 1.

In an embodiment, the warpage of the substrate 210 may be mitigated through the use of a warpage reduction layer 215 that is formed over the second surface 212 of the package substrate 210. In an embodiment, the warpage reduction layer 215 may comprise a mold material or the like. In an embodiment, a bottom surface 217 of the warpage reduction layer 215 may be substantially flat. In an embodiment, pads 213 on the second surface 212 of the package substrate 210 may be electrically coupled to pads 216 on the bottom surface 217 of the warpage reduction layer 215 by pillars 214. In an embodiment, the pillars 214 may have substantially vertical sidewalls. The pillars 214 may be plated up from the pads 213, or the pillars 214 may be discrete pillars that are bonded to the pads 213 (e.g., with a solder or the like). In an embodiment, a pad 216 may be provided on the bottom surface 217 of the warpage reduction layer 215 over each of the pillars 214. Such an embodiment may be useful for LGA interconnect approaches or the like.

Referring now to FIG. 2B, a cross-sectional illustration of an electronic package 200 is shown, in accordance with an additional embodiment. In an embodiment, the electronic package 200 in FIG. 2B may be similar to the electronic package 200 in FIG. 2A, with the exception of the warpage reduction layer 215. Instead of having a substantially flat bottom surface 217, the warpage reduction layer may be curved. In an embodiment, the curvature of the bottom surface 217 may be chosen in order to provide a desired amount of warpage control at elevated temperatures. For example, when the electronic package 200 is bonded to a board (not shown) with a BGA process using interconnects 218, the elevated temperature results in additional warpage that drives the bottom surface 217 to be substantially flat. In an embodiment, a curvature of the bottom surface 217 is different than a curvature of the second surface 212 of the package substrate 210.

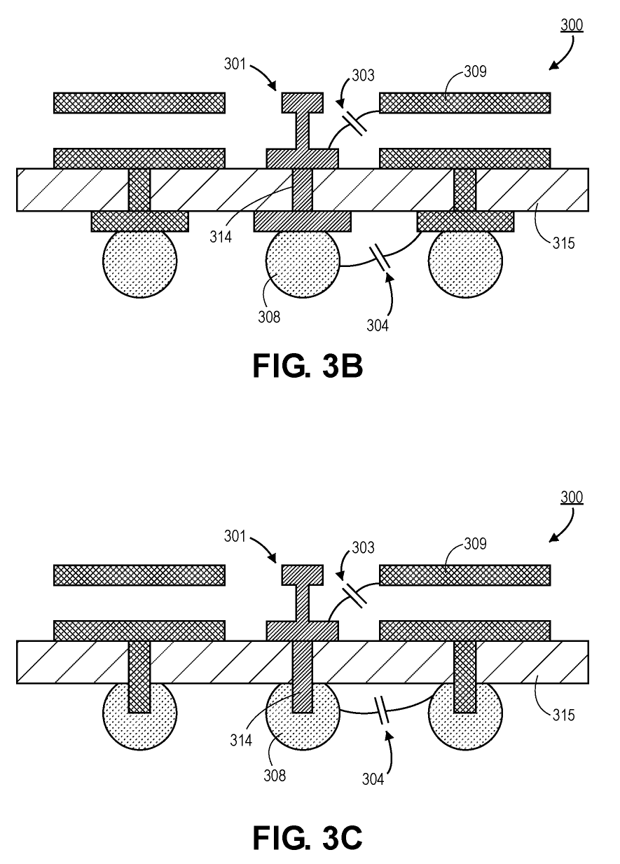

In addition to providing warpage mitigation, embodiments disclosed herein may also improve high speed I/O (HSIO) performance. For example, FIG. 3A is a schematic of a baseline BGA electronic package 300 (with the buildup layers omitted for simplicity). As shown, the pad of the interconnect structure 301 has a capacitance 303 with an adjacent ground plane 309, and the interconnect 308 also has a capacitance 304 with an adjacent ground plane 309. Particularly, it has been shown that the capacitances 303 and 304 are a limiting factor for signaling bandwidth.

However, as shown in FIG. 3B, the addition of warpage reduction layer 315 and pillar 314 to the interconnect structure 301 allows for significant improvements in the capacitance 303 and 304. For example, the improved flatness provided by the warpage reduction layer 315 allows for a reduction in a diameter of the pad below the pillar 314. Additionally, the thickness of the warpage reduction layer 315 may decrease capacitance since the distance between the signaling pad and the ground planes are increased. The size of the interconnect 308 (e.g., solder ball) can also be decreased since the planarity is improved. This may also decrease the capacitance 304.

Referring now to FIG. 3C, an additional construction of the electronic package 300 that further helps improve HSIO performance with a BGA approach is shown, in accordance with an embodiment. As shown, the interconnect 308 may be directly attached to the exposed pillar 314, so that the interconnect pad and its associated capacitance is entirely eliminated. In some embodiments, the interconnect 308 is attached to the pillar 314 before bonding to the board. In other embodiments, the interconnect 308 is provided on the board and the exposed pillars 314 are inserted into the interconnect 308 upon bonding.

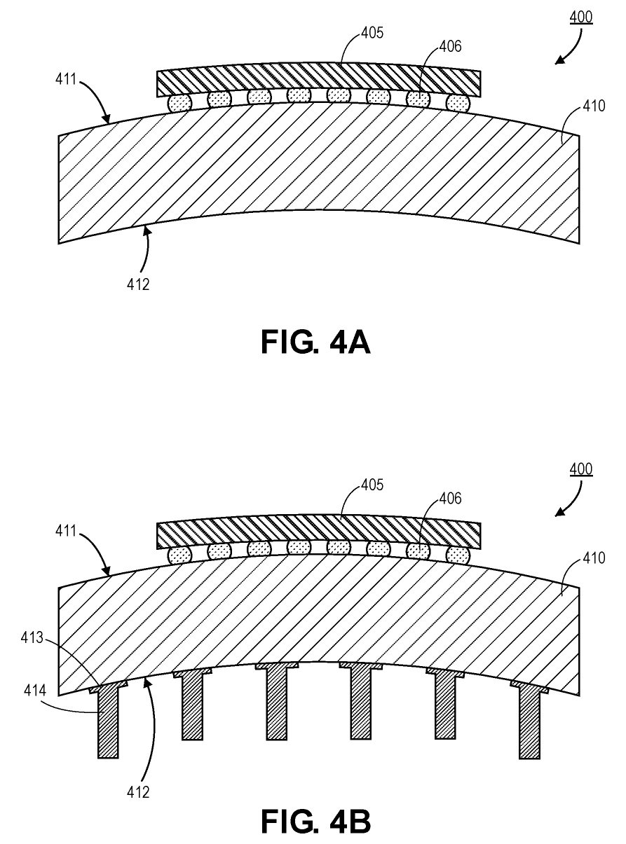

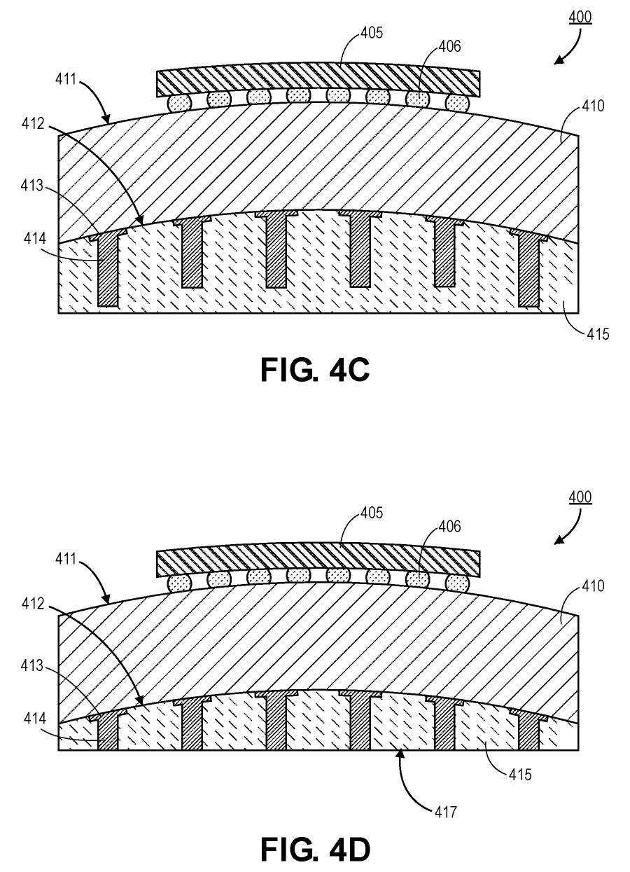

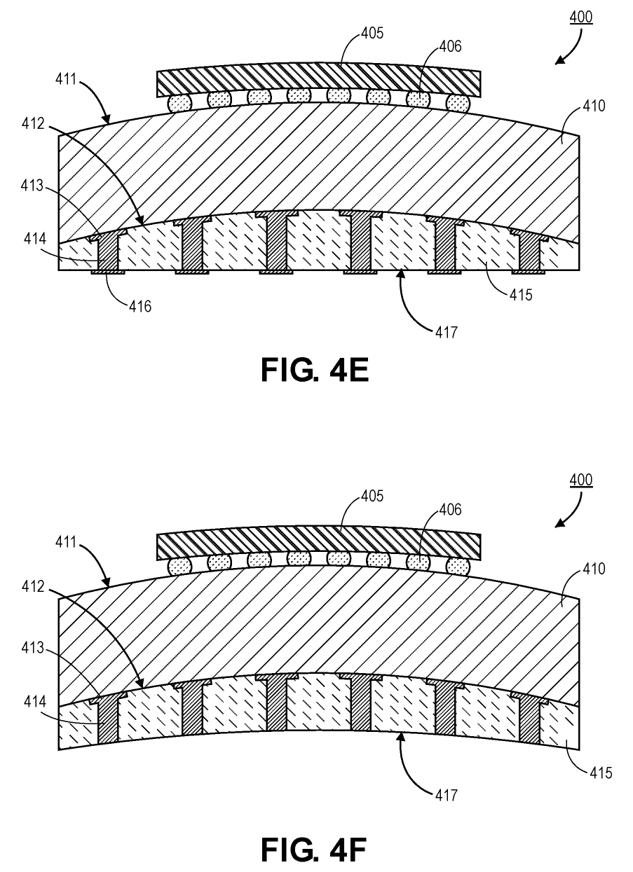

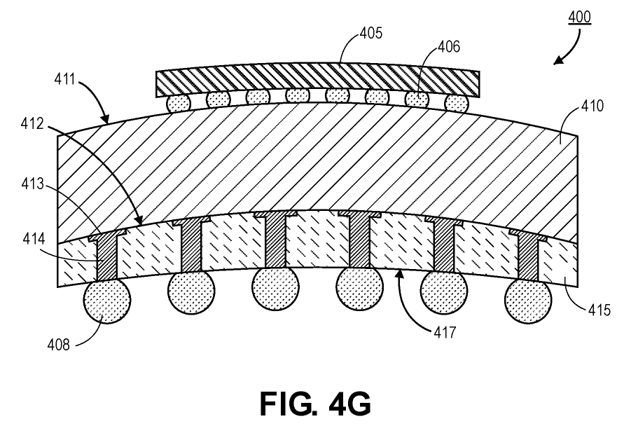

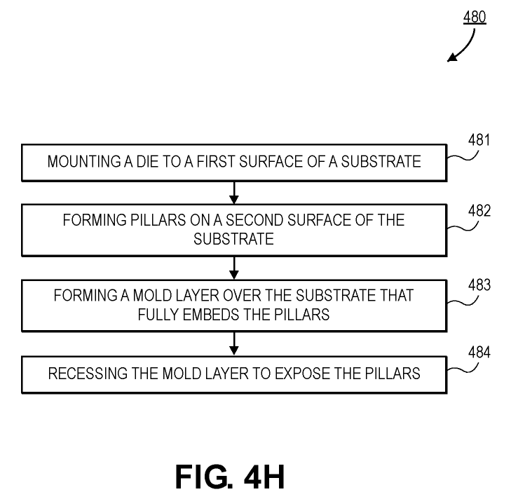

Referring now to FIGS. 4A – 4G, a series of cross-sectional illustrations depicting a process for forming a warpage reduction layer on an electronic package is shown, in accordance with an embodiment.

Referring now to FIG. 4A, a cross-sectional illustration of a portion of an electronic package 400 at a stage of manufacture is shown, in accordance with an embodiment. In an embodiment, the electronic package 400 may comprise a package substrate 410 with a first surface 411 and a second surface 412. In an embodiment, a die 405 may be electrically coupled to the first surface 411 of the package substrate 410 by interconnects 406. In an embodiment, the first surface 411 and the second surface 412 may be curved due to warpage induced by the CTE mismatch between the die 405 and the package substrate 410. In an embodiment, the die 405, the interconnects 406, and the package substrate 410 may be similar to corresponding features described in greater detail herein with respect to FIG. 1.

Referring now to FIG. 4B, a cross-sectional illustration of the electronic package 400 after pads 413 and pillars 414 are formed on the second surface 412 of the package substrate 410 is shown, in accordance with an embodiment. In an embodiment, the pads 413 may be formed with any suitable plating and/or patterning process. In an embodiment, the pillars 414 may be plated up from the pads 413, formed through mold via formation, attached by a bond via array approach, or the pillars 414 may be attached to the pads 413 (e.g., with a solder or the like). In one embodiment, premade electrically conductive pillars 414 are coupled to the pads 413 by applying a solder on the pads 413, dropping the pillars 414 onto the solder through a mask, and then reflowing the solder. That is, the pillars 414 may be formed in direct contact with the pads 413, or the pillars 414 may be electrically coupled to the pads 413 through a solder or the like.

Referring now to FIG. 4C, a cross-sectional illustration of the electronic package 400 after a warpage reduction layer 415 is formed over the second surface 412 of the package substrate 410 is shown, in accordance with an embodiment. In an embodiment, the warpage reduction layer 415 may be a mold layer or the like. For example, the warpage reduction layer 415 may be applied with a compression molding process, a transfer molding process, or the like. As shown, the warpage reduction layer 415 may fully embed the pillars 414. That is, the ends of the pillars 414 may be covered by the warpage reduction layer 415.

In an embodiment, the operations shown in FIGS. 4A – 4C may be implemented at the panel level or at the unit level. Additionally, the die 405 may be attached after the operations shown in FIGS. 4A – 4C. The subsequent processing operations may be implemented after singulation and the end-of-line units and attachment of any dies 405, stiffeners, integrated heat spreaders, and/or the like. This is because the inclusion of these additional components may change the warpage of the package substrate 410. That is, the planarization provided by the subsequent warpage reduction layer 415 may be implemented after the warpage of the electronic package 400 is substantially fixed.

Referring now to FIG. 4D, a cross-sectional illustration of the electronic package 400 after the warpage reduction layer 415 is recessed to expose ends of the pillars 414 is shown, in accordance with an embodiment. In an embodiment, the warpage reduction layer 415 is recessed with a polishing process (e.g., a chemical mechanical polishing (CMP) process), an etching process, or the like. As shown, ends of the pillars 414 may be substantially coplanar with a bottom surface 417 of the warpage reduction layer 415. The use of a substantially flat bottom surface 417 may be useful for lower temperature bonding processes, such as an LGA process. As shown, the pillars 414 may have non-uniform heights in order to account for the warpage of the package substrate 410.

Referring now to FIG. 4E, a cross-sectional illustration of the electronic package 400 after pads 416 are formed over the pillars 414 is shown, in accordance with an embodiment. In an embodiment, the pads 416 may be formed with any suitable deposition and/or patterning process. The pads 416 may be LGA pads or the like.

Referring now to FIG. 4F, a cross-sectional illustration of the electronic package 400 after an alternative recessing process for the warpage reduction layer 415 is shown, in accordance with an embodiment. As shown, the bottom surface 417 of the warpage reduction layer 415 may have a curvature. The curvature may be selectively implemented in order to account for additional warpage during high temperature bonding processes, such as SMT processes (e.g., BGA attach). In an embodiment, a controllable polishing and/or grinding processes, such as a scanning polishing process, may be used to provide a desired curvature to the warpage reduction layer 415.

Referring now to FIG. 4G, a cross-sectional illustration of the electronic package 400 after interconnects 408 are electrically coupled to the pillars 414 is shown, in accordance with an embodiment. As shown, the pillars 414 are directly contacting the interconnects 408. Though, in other embodiments, the pads (not shown) may be provided over the ends of the pillars 414 (e.g., similar to the embodiment shown in FIG. 3B).

Referring now to FIG. 4H, a process flow diagram that depicts a process 480 for forming a warpage reduction layer on a package substrate is shown, in accordance with an embodiment. In an embodiment, the process 480 may be similar to any of the processes described above with respect to FIGS. 4A – 4G. In an embodiment, the process 480 may begin with operation 481, which comprises mounting a die to a first surface of a substrate. In an embodiment, the die may be mounted to the first surface of the substrate with any suitable interconnects, such as any suitable FLI architecture.

In an embodiment, the process 480 may continue with operation 482, which comprises forming pillars on a second surface of the substrate. In an embodiment, the pillars may be electrically coupled to pads on the substrate. The pillars may be plated up from the pads, attached to the pads, or the like.

In an embodiment, the process 480 may continue with operation 483, which comprises forming a mold layer over the substrate. In an embodiment, the mold layer may fully embed the pillars. In an embodiment, the process 480 may continue with operation 484, which comprises recessing the mold layer to expose the pillars. In an embodiment, the recessed mold layer may have a substantially flat bottom surface (e.g., for an LGA approach), or the recessed mold layer may have a curved surface (e.g., for an SMT approach). In some embodiments, the operation 481 may be implemented after operation 484. In an embodiment, the process 480 may continue with forming pads on the exposed pillars and/or forming solder interconnects on the exposed pillars or pads.

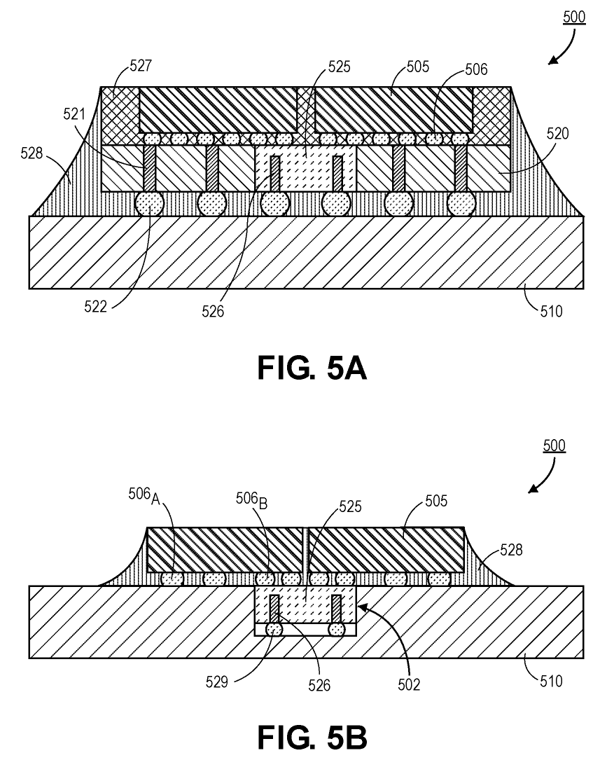

With respect to electronic packages with high bandwidth and high density interconnects used for heterogenous chiplet integration, large electronic packages are needed. Two options for such electronic packages include interposer-based solutions, such as shown in FIG. 5A, or bridge-based solutions, such as shown in FIG. 5B. However, as the chiplet-to-chiplet bump pitch shrinks, and the form factor of the package substrate grows, these two electronic packaging solutions run into significant challenges.

Referring now to FIG. 5A, a cross-sectional illustration of an electronic package 500 with an interposer-based solution is shown, in accordance with an embodiment. In an embodiment, the electronic package 500 comprises a package substrate 510. The package substrate 510 may be similar to any of the package substrates described in greater detail herein. For example, the package substrate 510 may comprise a core (e.g., a glass core or an organic core) with organic dielectric buildup layers over and/or under the core. In an embodiment, an interposer 520 may be coupled to the package substrate 510 by interconnects 522. The interconnects may be solder balls or the like.

In an embodiment, the interposer 520 may be a molded interposer substrate with a component 525 embedded within the interposer 520. In an embodiment, the component 525 may be a bridge substrate with or without vias 526. In an embodiment, pillars 521 may pass through the interposer 520 in order to electrically couple interconnects 522 to overlying interconnects 506 that electrically couple dies 505 to the interposer 520. While not shown, a buildup layer with electrical routing may be provided between the interposer 520 and the interconnects 506. In an embodiment, the component 525 may comprise one or more routing layers (not shown) that are configured to electrically couple the dies 505 to each other. An overmolding layer 527 may be provided around the dies 505, and a capillary underfill 528 may be provided around the structure over the package substrate 510.

With respect to electronic packages 500, such as the one shown in FIG. 5A, the large form factor leads to the package side bump (PSB) interconnects 522 having large pitches (e.g., greater than approximately 110µm). The loose PSB interconnect 522 pitch can be a challenge for off-package IO, which may be a desired feature for inclusion of high pin count memory (e.g., low-power double data rate (LPDDR) IO) on next generation HBM memory technologies.

Referring now to FIG. 5B, a cross-sectional illustration of an electronic package 500 with a bridge-based solution is shown, in accordance with an embodiment. In an embodiment, the electronic package 500 comprises a package substrate 510. The package substrate 510 may be similar to the package substrate 510 in FIG. 5A, with the exception of a cavity 502 that may be used to accommodate a component 525, such as a bridge. In an embodiment, interconnects 506A may electrically coupled the dies 505 to electrical routing (not shown) in the package substrate 510, and interconnects 506B may be used to electrically couple the dies 505 to the component 525. The interconnects 506A and 506B may have different diameters. In some embodiments, interconnects 529 may be provided between a bottom of the component 525 and the bottom of the cavity 502 to electrically couple vias 526 of the component 525 to electrical routing within the package substrate 510.

With respect to electronic packages 500, such as the one shown in FIG. 5B, the package substrate 510 uses laminated dielectric films (e.g., organic buildup film material) above the component 525. Such dielectric film is not planarized after lamination due to the type of dielectric material and due to the dielectric stack-up thickness variation and topography across the panel that comprises the package substrate 510. The thickness variation occurs both locally within a single unit (e.g., the package substrate 510 shown in FIG. 5B) and globally across the entire panel that comprises the package substrate 510. These Z-axis topography variations are significantly larger than typical buildup film thicknesses and via height tolerances. The Z-positional variation results in the need for higher solder volumes for the interconnects 506 between the dies 505 and the component 525 and/or between the dies 505 and the package substrate 510. Higher solder volume increases the CD of the interconnects 506 and limits the bump pitch reductions. Also, the component 525 may be coupled to pads (not shown) on the bottom surface of the cavity 502, which is a buried buildup layer. Since there may be layer-to-layer misalignment, the resulting structure may lead to X-direction and/or Y-direction positional tolerance between the interconnects 506B and the component via pads.

Accordingly, embodiments disclosed herein may include structures that can be used to improve the X, Y, and/or Z positional accuracy of the of bumping used for coupling structures to the component 525 (e.g., a bridge). The improved positional accuracy enables further bump pitch scaling over existing electronic package architectures..

Embodiments disclosed herein may uses panel-level processing of package substrates with organic cores or glass-cores for component integration. Instead of using carrier-panels (or carrier-wafers) with backside redistribution layers (RDLs) used in interposer-based architectures, embodiments disclosed herein may include electrically conductive pillars that are provided directly on the final package substrate. The component (e.g., a bridge die, a passive component, etc.) with fine pitch pillars embedded in a mold layer are also coupled (e.g., with solder interconnects) to the same package substrate. The panel comprising the package substrate may then be overmolded. The pillars over the package substrate and the component may then be revealed through a panel grinding process (e.g., CMP). In some embodiments, an optional topside RDL may be added over the mold layer and the pillars prior to solder bumping used to provide interconnects to the overlying dies. Thereafter, the panel may be singulated and the overlying dies may be attached. While a panel level process is described herein, some embodiments may also include a similar process implemented at the unit and/or device level.

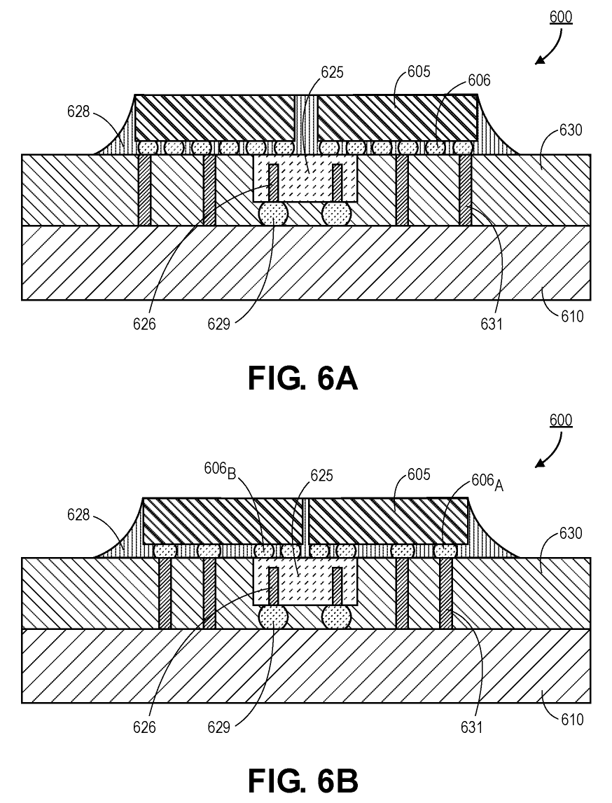

Referring now to FIGS. 6A and 6B, cross-sectional illustrations of electronic packages 600 that incorporate mold extension layers that can be used to improve positional accuracy of interconnects and enable interconnect pitch scaling are shown, in accordance with various embodiments. In FIG. 6A, the electronic package 600 comprises a package substrate 610. In an embodiment, the package substrate 610 may be similar to any of the package substrates described in greater detail herein. For example, the package substrate may comprise a glass core or an organic core with organic dielectric buildup layers over and/or under the core.

In an embodiment, a mold extension layer 630 may be provided over a surface of the package substrate 610. In an embodiment, the mold extension layer 630 (which may sometimes be referred to as a first mold layer) may comprise an epoxy material, and organic buildup film (with one or more layers), or any other suitable electrically insulating material. In an embodiment, first pillars 631 may extend up from the package substrate 610 through a thickness of the mold layer 630. The first pillars 631 may comprise any suitable electrically conductive material, such as copper. The first pillars 631 may have substantially vertical sidewalls. The first pillars 631 may be plated or otherwise mounted to the package substrate 610 (e.g., by solder or the like). In an embodiment, the first pillars 631 may be electrically coupled to pads (not shown) on a surface of the package substrate 610.

In an embodiment, a component 625 may also be embedded within the mold layer 630. In the case of a component 625 with vias 626 through at least a partial thickness of the component 625, the component 625 may be electrically coupled to pads (not shown) on the surface of the package substrate 610 by interconnects 629, such as solder bumps or the like. In an embodiment, the component 625 may be a bridge that is configured to electrically couple dies 605 together. For example a pair of dies 605 may both at least partially overlap the component 625. Though, in other embodiments, the component 625 may be located under a single die 605 or outside a footprint of any of the dies 605. In some embodiments, the component 625 may be a passive device, such as acapacitor, an inductor, or the like. In an embodiment, the component may comprise a glass layer, a silicon layer, or the like.

As shown in FIG. 6A, the dies 605 (which may include a capillary underfill 628) may be electrically coupled to the pillars 631 and/or the component 625 by interconnects 606. In the illustrated embodiment, the interconnects 606 may have substantially uniform dimensions. Though, as shown in FIG. 6B, interconnects 606A between the dies 605 and the pillars 631 may have a first dimension and the interconnects 606B between the dies 605 and the component 625 may have a second (smaller) dimension that allows for finer pitch connections.

In the embodiments shown in FIGS. 6A and 6B, the interconnects 606A and 606B are directly on the mold layer 630. Though, in other embodiments, one or more RDLs (not shown) may be provided over a top surface of the mold layer 630. Such an embodiment may allow for more flexible routing between the dies 605 and the pillars 631. Such an embodiment may allow for the fine pitch interconnects 606A to be translated to the looser pitch of the pillars 631. The embodiment shown in FIG. 6B may be more manufacturing friendly when an RDL is not used since there may not need to be any pitch translation between the pillars 631 and the interconnects 606A.

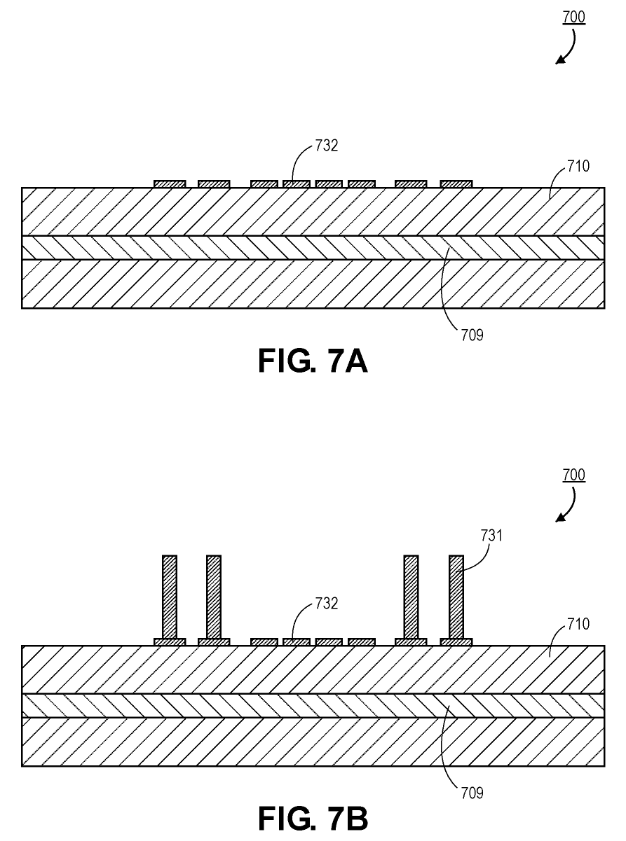

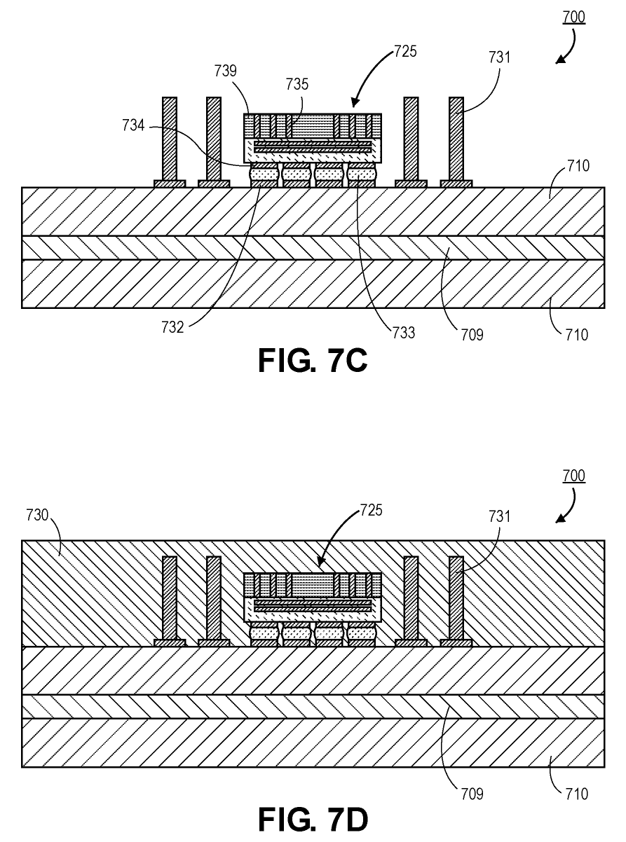

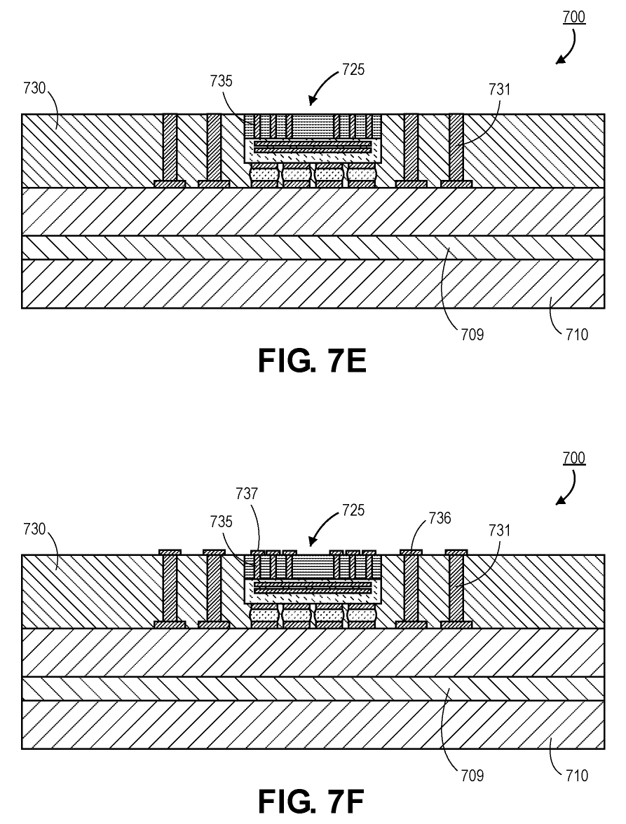

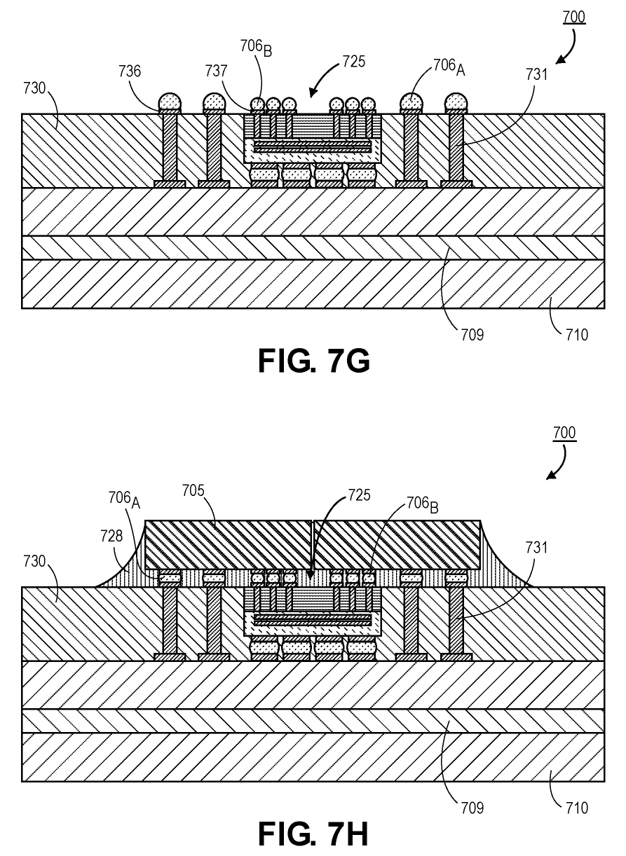

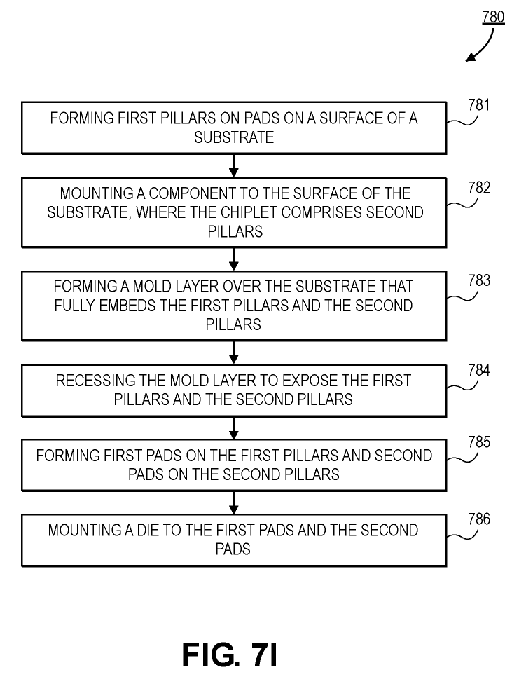

Referring now to FIGS. 7A – 7H, a series of cross-sectional illustrations that depict a process for forming an electronic package 700 with a mold extension layer 730 is shown, in accordance with an embodiment. The process flow shown in FIGS. 7A – 7H may produce an electronic package 700 similar to the electronic package 600 in FIG. 6B. Though, it is to be appreciated that electronic systems similar to the electronic package 600 in FIG. 6A may be manufactured with similar processing operations, especially when an RDL is added over the mold extension layer 730.

Referring now to FIG. 7A, a cross-sectional illustration of a portion of an electronic package 700 at a stage of manufacture is shown, in accordance with an embodiment. In an embodiment, the electronic package 700 may comprise a package substrate 710. The package substrate 710 may comprise a core 709, such as a glass core or an organic core.

In the case of a glass core 709, the glass core 709 may be substantially all glass. The glass core 709 may be a solid mass comprising a glass material with an amorphous crystal structure where the solid glass core may also include various structures – such as vias, cavities, channels, or other features – that are filled with one or more other materials (e.g., metals, metal alloys, dielectric materials, etc.). As such, glass core 709 may be distinguished from, for example, the “prepreg” or “FR4” core of a Printed Circuit Board (PCB) substrate which typically comprises glass fibers embedded in a resinous organic material, such as an epoxy.

The glass core 709 may have any suitable dimensions. In a particular embodiment, the glass core 709 may have a thickness that is approximately 50µm or greater. For example, the thickness of the glass core 709 may be between approximately 50µm and approximately 1.4mm. Though, smaller or larger thicknesses may also be used. The glass core 709 may have edge dimensions (e.g., length, width, etc.) that are approximately 10mm or greater. For example, edge dimensions may be between approximately 10mm to approximately 250mm. Though, larger or smaller edge dimensions may also be used. More generally, the area dimensions of the glass core 709 (from an overhead plan view) may be between approximately 10mm x 10mm and approximately 250mm x 250mm. In an embodiment, the glass core 709 may have a first side that is perpendicular or orthogonal to a second side. In a more general embodiment, the glass core 709 may comprise a rectangular prism volume with sections (e.g., vias) removed and filled with other materials (e.g., metal, etc.).

The glass core 709 may comprise a single monolithic layer of glass. In other embodiments, the glass core 709 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 709 may each have a thickness less than approximately 50µm. For example, discrete layers of glass in the glass core 709 may have thicknesses between approximately 25µm and approximately 50µm. Though, discrete layers of glass may have larger or smaller thicknesses in some embodiments. As used herein, “approximately” may refer to a range of values within ten percent of the stated value. For example approximately 50µm may refer to a range between 45µm and 55µm.

The glass core 709 may be any suitable glass formulation that has the necessary mechanical robustness and compatibility with semiconductor packaging manufacturing and assembly processes. For example, the glass core 709 may comprise aluminosilicate glass, borosilicate glass, alumino-borosilicate glass, silica, fused silica, or the like. In some embodiments, the glass core 709 may include one or more additives, such as, but not limited to, Al2O3, B2O3, MgO, CaO, SrO, BaO, SnO2, Na2O, K2O, SrO, P2O3, ZrO2, Li2O, Ti, or Zn. More generally, the glass core 709 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 709 may comprise at least 23 percent silicon (by weight) and at least 26 percent oxygen (by weight). In some embodiments, the glass core 709 may further comprise at least 5 percent aluminum (by weight).

In an embodiment, the package substrate 710 may comprise pads 732. The pads 732 may be provided on a surface of the package substrate 710. In an embodiment, the pads 732 may be electrically coupled to electrical routing (not shown) within the package substrate 710 and/or through the core 709. For example, the electrical routing may include pads, traces, vias, and/or the like.

Referring now to FIG. 7B, a cross-sectional illustration of the electronic package 700 after pillars 731 are formed over some of the pads 732 is shown, in accordance with an embodiment. In an embodiment, the pillars 731 may be high aspect ratio features (e.g., with a height:width ratio of 3:1 or greater, 5:1 or greater, or 10:1 or greater). The pillars 731 may be directly plated up from the pads 732. In other embodiments, the pillars 731 may be discrete structures that are attached to the pads 732 (e.g., with a solder or the like).

Referring now to FIG. 7C, a cross-sectional illustration of the electronic package 700 after a component 725 is coupled to the package substrate 710 is shown, in accordance with an embodiment. In an embodiment, the component 725 may comprise a bridge device. For example, the component 725 may comprise one or more routing layers (e.g., indicated as the horizontal rectangles) that allows for lateral electrical routing. In an embodiment, the component 725 may comprise pads 734 that are electrically coupled to pads 732 on the package substrate 710 by interconnects 733 (e.g., solder bumps). In an embodiment, component pillars 735 may be electrically coupled to the routing layer and extend up from the routing layer. The component pillars 735 may be embedded in a component mold layer 739. The component 725 may be surrounded by the pillars 731. Though, in other embodiments, the component 725 may be outside of the pillars 731.

While the component 725 is shown as being a bridge in FIG. 7C, embodiments may include any type of component that is useful for the electronic package 700. For example, the component 725 may comprise a passive component (e.g., an inductor, a capacitor, or the like), a memory device, a transistor-based device, and/or the like. Further, while a single component 725 is shown in FIG. 7C, embodiments may comprise any number of components 725.

Referring now to FIG. 7D, a cross-sectional illustration of an electronic package 700 after a mold extension layer 730 is formed over the package substrate 710 is shown, in accordance with an embodiment. In an embodiment, the mold extension layer 730 (which may also be referred to as a mold layer) may be formed with any molding process. The mold layer 730 may comprise an epoxy material or any other suitable electrically insulating material. In an embodiment, the mold layer 730 may be formed to a thickness that fully embeds the pillars 731 and the component 725. That is, the top surfaces of the pillars 731 and the sidewall surfaces of the pillars 731 may be covered by the mold layer 730.

Referring now to FIG. 7E, a cross-sectional illustration of the electronic package 700 after the mold layer 730 is recessed is shown, in accordance with an embodiment. In an embodiment, the mold layer 730 may be recessed with a polishing or grinding process, such as a CMP process or the like. In an embodiment, the mold layer 730 is recessed so that the top surfaces of the pillars 731 and component pillars 735 are exposed and substantially coplanar with each other. In some embodiments, the recessing process may also recess a portion of the mold layer of the component 725. The polishing process may result in the mold layer 730 having a substantially flat surface. More generally, a flatness of a top surface of the mold layer 730 is flatter than a flatness of a top surface of the top surface of the package substrate 710. As such, the Z-height variation that limits pitch scaling is avoided.

Referring now to FIG. 7F, a cross-sectional illustration of the electronic package 700 after pads 736 and 737 are formed over the exposed pillars 731 and component pillars 735, respectively, is shown, in accordance with an embodiment. In an embodiment, the pads 736 may be formed with any suitable plating and/or patterning processing. While pads are shown as being formed directly on the surface of the mold layer 730, embodiments may also include forming one or more RDLs over the mold layer 730. In some embodiments, the pads 736 over the pillars 731 and the component pillars 735 may be formed with a single lithography process. As such, the X-direction and Y-direction positional variation is substantially eliminated. Accordingly, the positional variation for the pads 736 and pads 737 in the X-direction, Y-direction, and the Z-direction are all reduced or substantially eliminated. This allows for improved pitch scaling for subsequently formed interconnects. For example, pitches of 10µm or smaller may be enabled in some embodiments.

Referring now to FIG. 7G, a cross-sectional illustration of the electronic package 700 after interconnects 706 are formed over the pads 736 is shown, inaccordance with an embodiment. In an embodiment, the interconnects 706 may comprise solder bumps or the like. As shown, the interconnects 706A over the pads 736 may have a first diameter, and the interconnects 706B over the pads 737 may have a second (smaller) diameter. Though, in other embodiments the interconnects 706A and 706B may have substantially similar diameters.

Referring now to FIG. 7H, a cross-sectional illustration of the electronic package 700 after dies 705 are coupled to the interconnects 706A and 706B is shown, in accordance with an embodiment. In an embodiment, the dies 705 may be any type of die, such as a processor, a memory die, a communications die, and/or the like. In some embodiments, a capillary underfill 728 may be provided around and/or under the dies 705. In the case of a panel level assembly, the panel may be singulated into individual units prior to mounting the dies 705 to the package substrate 710.

Referring now to FIG. 7I, a process flow diagram that describes a process 780 for forming an electronic package with a mold extension layer is shown, in accordance with an embodiment. In an embodiment, the process 780 may be similar to the process described above with respect to FIGS. 7A – 7H. In an embodiment, the process 780 may begin with operation 781, which comprises forming first pillars on a surface of a substrate. In an embodiment, the first pillars may be high aspect ratio pillars that are formed with an electroplating process or the like. In an embodiment, the substrate may be a package substrate (e.g., with an organic core or a glass core).

In an embodiment, the process 780 may continue with operation 782, which comprises mounting a component, such as a chiplet, a bridge, or the like, to the surface of the substrate. In an embodiment, the chiplet comprises second pillars. The second pillars may be embedded in a layer, such as an epoxy mold layer.

In an embodiment, the process 780 may continue with operation 783, which comprises forming a mold layer over the substrate that fully embeds the first pillars and the second pillars. In an embodiment, the mold layer may be an epoxy based material, a buildup film or the like.

In an embodiment, the process 780 may continue with operation 784, which comprises recessing the mold layer to expose the first pillars and the second pillars. For example, a CMP process or the like may be used to recess the mold layer. In some embodiments, the recessing process may remove portions of the first pillars and/or the second pillars. The recessed surface of the mold layer may be substantially flat. As such, any Z-height variation of the substrate may be substantially eliminated.

In an embodiment, the process 780 may continue with operation 785, which comprises forming first pads on the first pillars and second pads on the second pillars. In an embodiment, the first pads and the second pads may be formed with a single patterning process. As such, any X-direction and/or Y-direction position variation is substantially eliminated. The removal of position variation in the X, Y, and Z direction allows for improved pitch scaling.

In an embodiment, the process 780 may continue with operation 786, which comprises mounting a die to the first pads and the second pads. In an embodiment, the die may be mounted to the first pads and the second pads with interconnects, such as solder balls or the like. Due to the improved pitch scaling, embodiments allow for increased interconnect density between the die and the substrate.

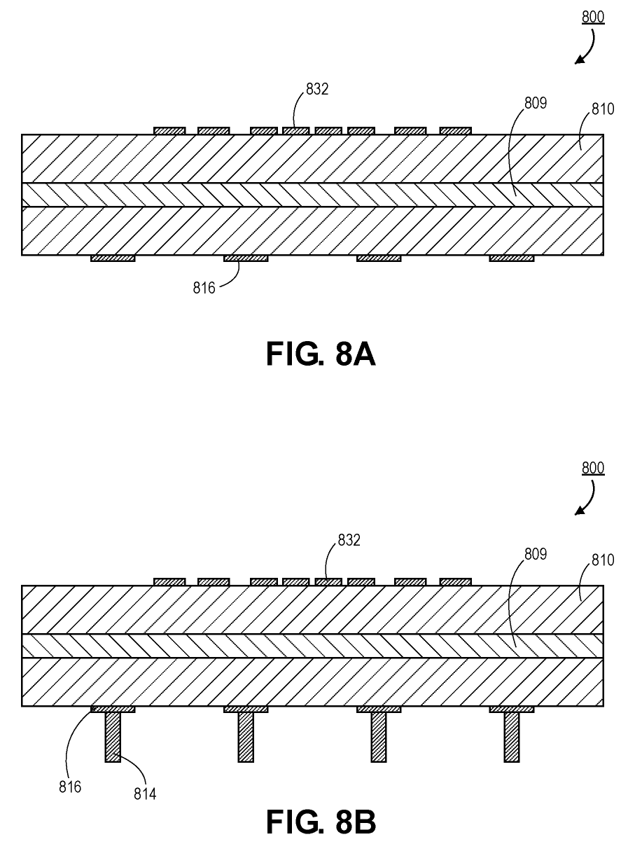

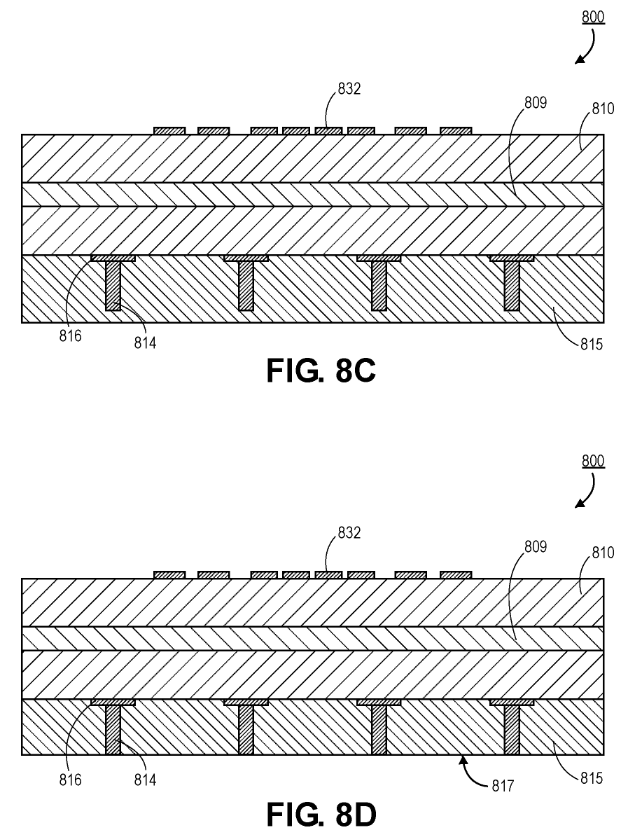

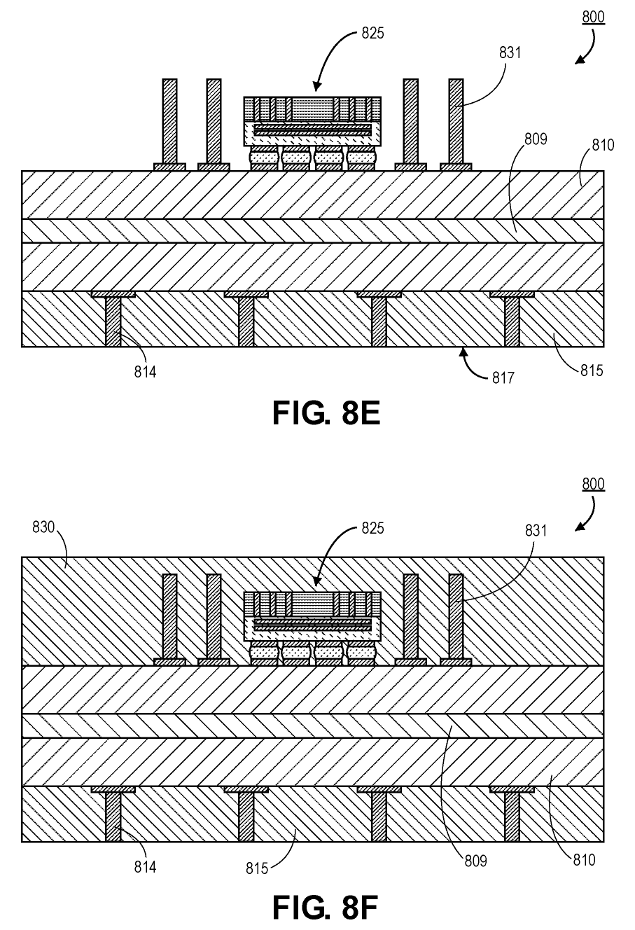

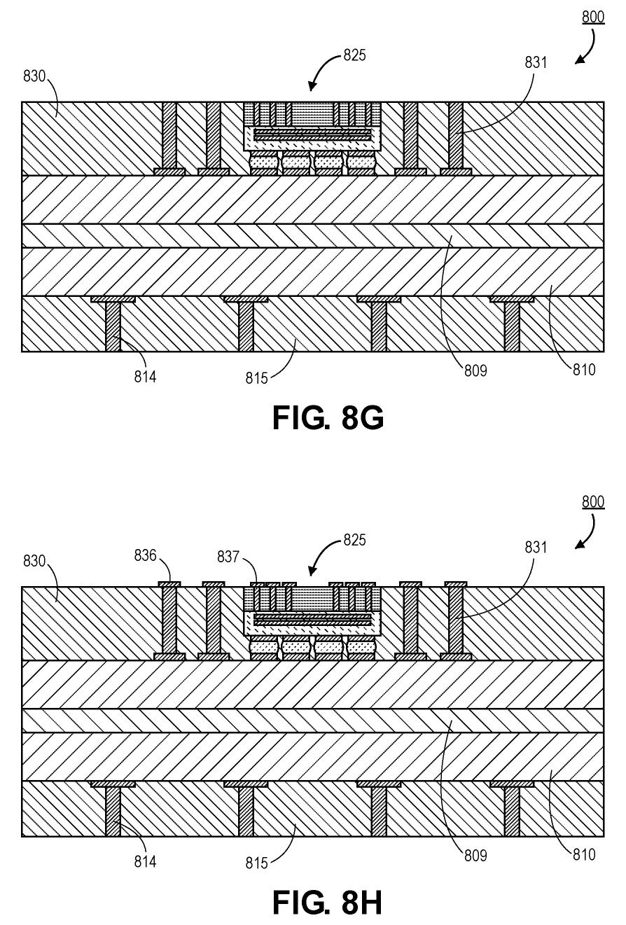

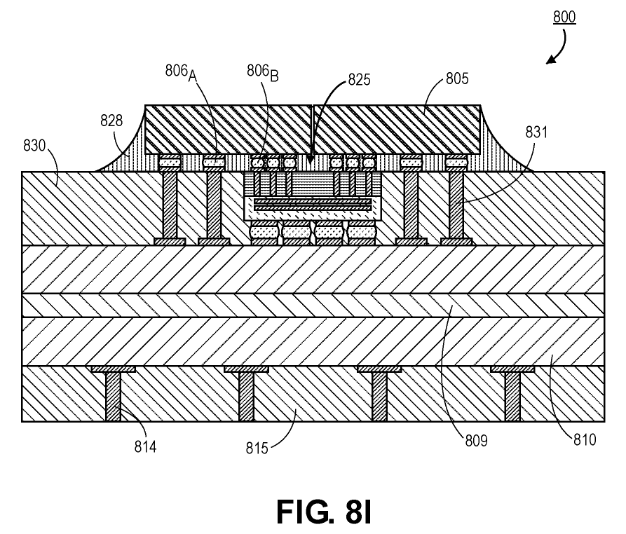

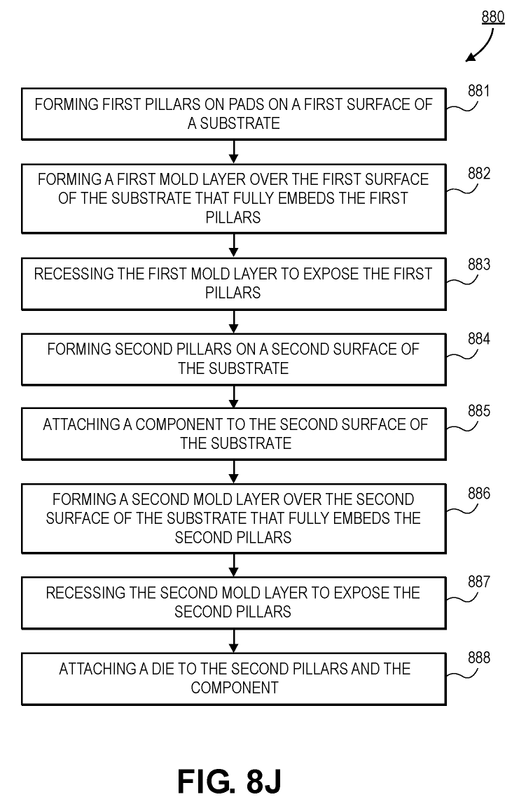

In the embodiments described above with respect to FIGS. 7A – 7I, the planarization process of the mold layer 730 is implemented without treating any Z-height variation (e.g., warpage, thickness variation of buildup layers, etc.) on a bottom surface of the package substrate 710. In some instances, this extra Z-height variation may impact the flatness of the top surface of the mold layer 730. Accordingly, some embodiments may further include a bottom mold extension layer over the bottom surface of the package substrate 710. Such an embodiment may further improve overall flatness and enable even further scaling of the component interconnects and the pillar interconnects. An example of such an embodiment is shown in FIGS. 8A – 8I.

Referring now to FIG. 8A, a cross-sectional illustration of a portion of an electronic package 800 at a stage of manufacture is shown, in accordance with an embodiment. In an embodiment, the electronic package 800 may comprise a package substrate 810. The package substrate 810 may comprise a core 809, such as a glass core or an organic core. In an embodiment, the package substrate 810 may be similar to any of the package substrates described in greater detail herein. For example, due to thickness non-uniformity of the package substrate 810, a top and/or bottom surface of the package substrate 810 may not be substantially flat. In an embodiment, pads 832 may be formed on the top surface of the package substrate 810, and pads 816 may be formed on the bottom surface of the package substrate 810.

Referring now to FIG. 8B, a cross-sectional illustration of the electronic package 800 after pillars 814 are formed the pads 816 is shown, in accordance with an embodiment. In an embodiment, the pillars 814 may be high aspect ratio features (e.g., with a height:width ratio of 3:1 or greater, 5:1 or greater, or 10:1 or greater). The pillars 814 may be directly plated up from the pads 816. In other embodiments, the pillars 814 may be discrete structures that are attached to the pads 816 (e.g., with a solder or the like).

Referring now to FIG. 8C, a cross-sectional illustration of an electronic package 800 after a lower mold extension layer 815 is formed over the bottom surface of the package substrate 810 is shown, in accordance with an embodiment. In an embodiment, the lower mold extension layer 815 (which may also be referred to as a bottom mold layer) may be formed with any molding process. The lower mold layer 815 may comprise an epoxy material or any other suitable electrically insulating material. In an embodiment, the lower mold layer 815 may be formed to a thickness that fully embeds the pillars 814. That is, the bottom surfaces of the pillars 814 and the sidewall surfaces of the pillars 814 may be covered by the lower mold layer 815.

Referring now to FIG. 8D, a cross-sectional illustration of the electronic package 800 after the lower mold layer 815 is recessed is shown, in accordance with an embodiment. In an embodiment, the lower mold layer 815 may be recessed with a polishing or grinding process, such as a CMP process or the like. In an embodiment, the lower mold layer 815 is recessed so that the top surfaces of the pillars 814 are exposed. The polishing process may result in a bottom mold layer that has a substantially flat surface 817. As such, the Z-height variation (e.g., due to warpage, thickness variation of buildup layers in the package substrate 810, etc.) that limits pitch scaling is avoided.

Referring now to FIG. 8E, a cross-sectional illustration of the electronic package 800 after pillars 831 and a component 825 are provided over some of the pads 832 is shown, in accordance with an embodiment. In an embodiment, the pillars 831 may be similar to the pillars 731 described in greater detail above, and the component 825 may be similar to the component 725 described in greater detail above. For example, the component 825 may be a bridge, a passive device, an active device, or the like.

Referring now to FIG. 8F, a cross-sectional illustration of an electronic package 800 after an upper mold extension layer 830 is formed over the package substrate 810 is shown, in accordance with an embodiment. In an embodiment, the upper mold extension layer 830 (which may also be referred to as an upper mold layer) may be formed with any molding process. The upper mold layer 830 may comprise an epoxy material or any other suitable electrically insulating material. In an embodiment, the upper mold layer 830 may be formed to a thickness that fully embeds the pillars 831 and the component 825. That is, the top surfaces of the pillars 831 and the sidewall surfaces of the pillars 831 may be covered by the mold layer 830.

Referring now to FIG. 8G, a cross-sectional illustration of the electronic package 800 after the upper mold layer 830 is recessed is shown, in accordance with an embodiment. In an embodiment, the upper mold layer 830 may be recessed with a polishing or grinding process, such as a CMP process or the like. In an embodiment, the upper mold layer 830 is recessed so that the top surfaces of the pillars 831 and component 825 are exposed and substantially coplanar with each other. In some embodiments, the recessing process may also recess a portion of a mold layer of the component 825. The polishing process may result in the upper mold layer 830 having a substantially flat surface. Further, since the bottom surface of the lower mold layer 815 is planarized, the overall flatness of the electronic package 800 is improved compared to other embodiments. As such, the Z-height variation that limits pitch scaling is avoided.

Referring now to FIG. 8H, a cross-sectional illustration of the electronic package 800 after pads 836 and 837 are formed over the exposed pillars 831 and pillars of the component 825, respectively, is shown, in accordance with an embodiment. In an embodiment, the pads 836 may be formed with any suitable plating and/or patterning processing. While pads are shown as being formed directly on the surface of the upper mold layer 830, embodiments may also include forming one or more RDLs over the upper mold layer 830. In some embodiments, the pads 836 over the pillars 831 and the pads 837 over the component 325 pillars may be formed with a single lithography process. As such, the X-direction and Y-direction positional variation is substantially eliminated. Accordingly, the positional variation for the pads 836 and pads 837 in the X-direction, Y-direction, and the Z-direction are all eliminated. This allows for improved pitch scaling for subsequently formed interconnects. For example, pitches of 10µm or smaller may be enabled in some embodiments.

Referring now to FIG. 8I, a cross-sectional illustration of the electronic package 800 after interconnects 806 are formed over the pads 836 and 837, and dies 805 are coupled to the interconnects 806 is shown, in accordance with an embodiment. In an embodiment, the interconnects 806 may comprise solder bumps or the like. As shown, the interconnects 806A over the pads 836 may have a first diameter, and the interconnects 806B over the pads 837 may have a second (smaller) diameter. Though, in other embodiments the diameters may be the same.

In an embodiment, the dies 805 may be any type of die, such as a processor, a memory die, a communications die, and/or the like. In some embodiments, a capillary underfill 828 may be provided around and/or under the dies 805. In the case of a panel level assembly, the panel may be singulated into individual units prior to mounting the dies 805 to the package substrate 810.

Referring now to FIG. 8J, a process flow diagram that describes a process 880 for forming an electronic package with a mold extension layer is shown, in accordance with an embodiment. In an embodiment, the process 880 may be similar to the process described above with respect to FIGS. 8A – 8I. In an embodiment, the process 880 may begin with operation 881, which comprises forming first pillars on pads on a first surface of a substrate. In an embodiment, the first pillars may be high aspect ratio pillars that are formed with an electroplating process or the like. In an embodiment, the substrate may be a package substrate (e.g., with an organic core or a glass core).

In an embodiment, the process 880 may continue with operation 882, which comprises forming a first mold layer over the first surface of the substrate. In an embodiment, the first mold layer may fully embed the first pillars.

In an embodiment, the process 880 may continue with operation 883, which comprises recessing the first mold layer to expose the first pillars. For example, a CMP process or the like may be used to recess the mold layer. In some embodiments, the recessing process may remove portions of the first pillars. The recessed surface of the mold layer may be substantially flat. As such, any Z-height variation of the substrate may be substantially eliminated.

In an embodiment, the process 880 may continue with operation 884, which comprises forming second pillars on a second surface of a substrate. In an embodiment, the second pillars may be high aspect ratio pillars that are formed with an electroplating process or the like.

In an embodiment, the process 880 may continue with operation 885, which comprises mounting a component, such as a chiplet, a bridge, or the like, to the second surface of the substrate. In an embodiment, the component may comprise third pillars. The third pillars may be embedded in a layer, such as an epoxy mold layer.

In an embodiment, the process 880 may continue with operation 886, which comprises forming a second mold layer over the second surface of the substrate that fully embeds the second pillars and the component. In an embodiment, the second mold layer may be an epoxy based material, a buildup film or the like.

In an embodiment, the process 880 may continue with operation 887, which comprises recessing the second mold layer to expose the second pillars and the third pillars. For example, a CMP process or the like may be used to recess the second mold layer. In some embodiments, the recessing process may remove portions of the second pillars and/or the third pillars. The recessed surface of the mold layer may be substantially flat. As such, any Z-height variation of the substrate may be substantially eliminated.

In an embodiment, the process 880 may continue with operation 888, which comprises attaching a die to the second pillars and the component. In an embodiment, pads may be formed on the second pillars and the third pillars. In an embodiment, the pads may be formed with a single patterning process. As such, any X-direction and/or Y-direction position variation is substantially eliminated. The removal of position variation in the X, Y, and Z direction allows for improved pitch scaling. Due to the improved pitch scaling, embodiments allow for increased interconnect density between the die and the substrate.

As noted in the embodiments described above, frontside mold extension layers on conventional package substrates may be used for improving interconnect bump Z-topology. However, Z-thickness variation across the panel comprising the package substrate, especially in the case of high dielectric buildup layer count package substrates, may be over 50µm. Such high thickness variations may result in the need for fine pitch (e.g., approximately 15µm to approximately 25µm pitch) pillars on the component to be very tall (e.g., greater than approximately 70µm). Such high aspect ratios for the pillars are difficult manufacture and may also affect negatively impact thermocompression bonding (TCB) attach of the component to the package substrate due to thermal resistance issues since a thick mold layer is needed above the component to surround the pillars.

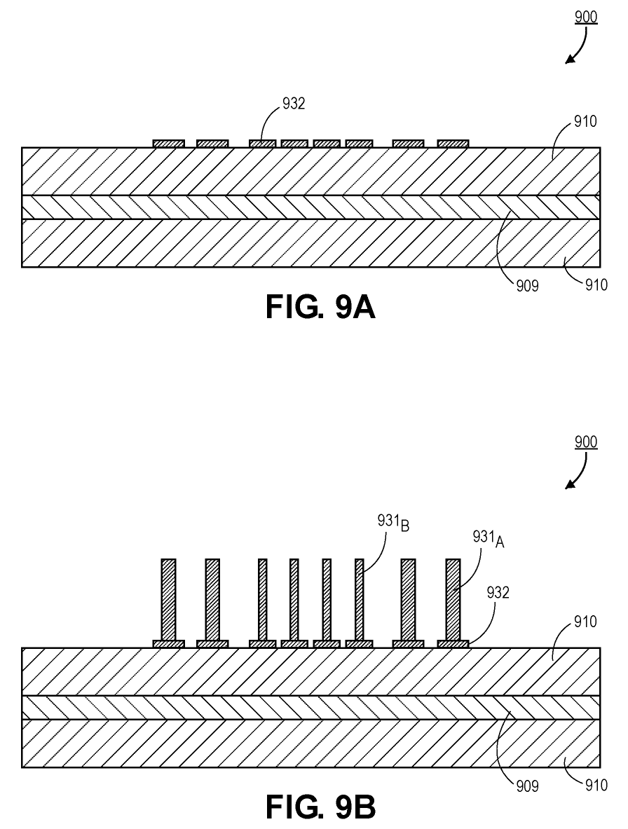

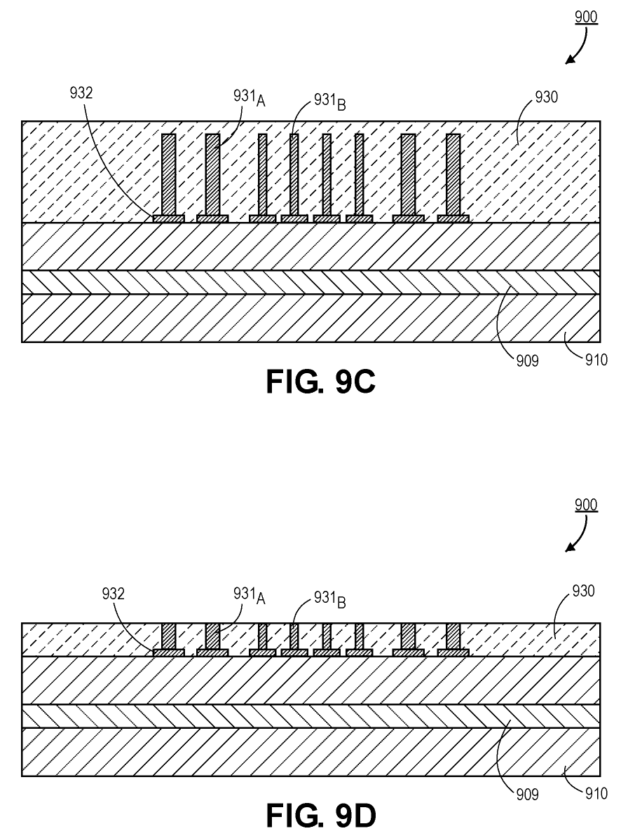

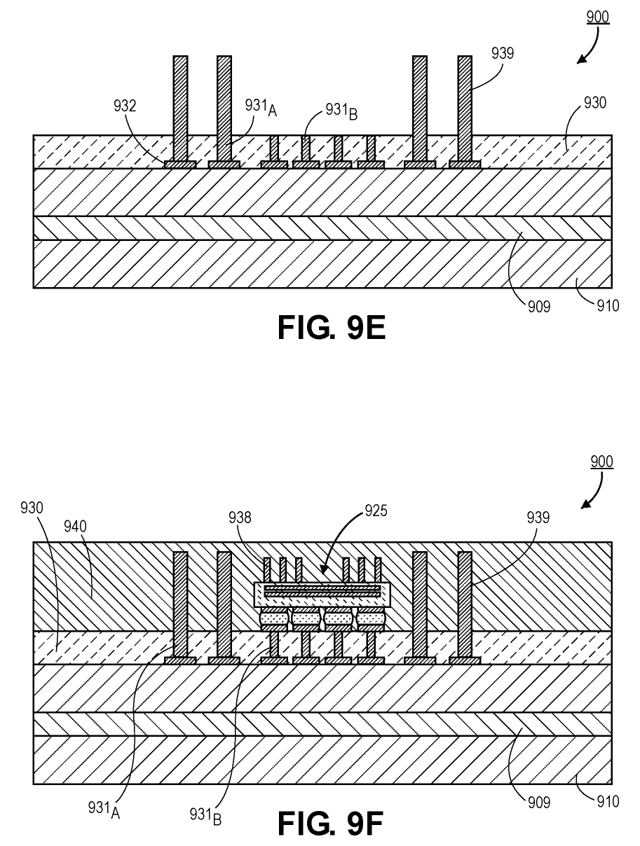

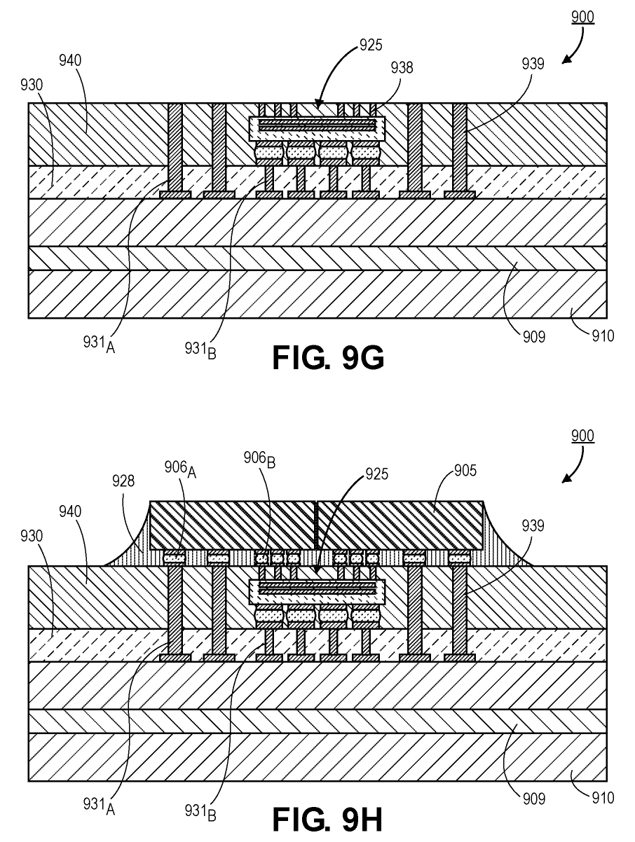

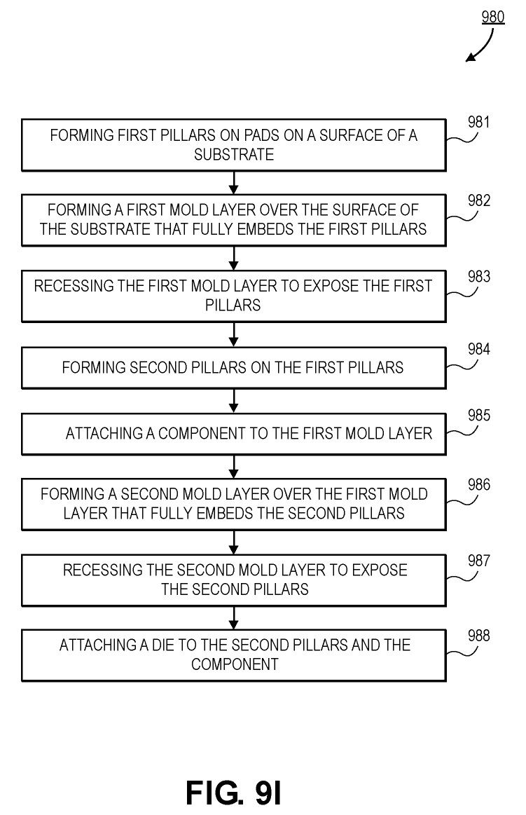

Accordingly, embodiments may include a frontside Z-reset mold layer between the mold extension layer and the package substrate in order to provide a uniform Z-thickness across the entire panel. The frontside Z-reset mold layer enables a mold grinding process that planarizes the substrate panel prior to attaching the component to the package substrate. That is, embodiments allow for improved component and component pillar coplanarity. Such an embodiment may be used to enable fine pitch pillars on the component. After the frontside Z-reset mold layer is added, previously disclosed mold extension layers (e.g., a frontside mold extension layer and/or a backside mold extension layer) may be added using processes similar to those described in greater detail herein. Similarly, a backside Z-reset mold layer may be combined with a frontside Z-reset mold layer in accordance with other embodiments described herein. Various mold material properties for any of the reset layers and/or extension layers may be tuned to manage inherent warpage of the package substrate and/or the final assembled electronic package. An example of a process for forming an electronic package with a Z-reset mold layer is shown in FIGS. 9A – 9H.

Referring now to FIG. 9A, a cross-sectional illustration of a portion of an electronic package 900 at a stage of manufacture is shown, in accordance with an embodiment. In an embodiment, the electronic package 900 may comprise a package substrate 910. The package substrate 910 may comprise a core 909, such as a glass core or an organic core. In an embodiment, the package substrate 910 may be similar to any of the package substrates described in greater detail herein. In an embodiment, pads 932 may be formed on the top surface of the package substrate 910.

Referring now to FIG. 9B, a cross-sectional illustration of the electronic package 900 after pillars 931A and 931B are formed over the pads 932 is shown, in accordance with an embodiment. In an embodiment, the pillars 931 may be high aspect ratio features (e.g., with a height:width ratio of 3:1 or greater, 5:1 or greater, or 10:1 or greater). The pillars 931 may be directly plated up from the pads 932. In other embodiments, the pillars 931 may be discrete structures that are attached to the pads 932 (e.g., with a solder or the like). In an embodiment, the pillars 931A may be used to electrically couple the package substrate 910 to overlying dies (added in a subsequent processing operation), and the pillars 931B may be used to electrically couple the package substrate 910 to a component (added in a subsequent processing operation). The pillars 931A and 931B may have different widths. For example, the pillars 931B may be narrower than the pillars 931A.

Referring now to FIG. 9C, a cross-sectional illustration of the electronic package 900 after a Z-reset mold layer 930 is formed over the package substrate 910 is shown, in accordance with an embodiment. In an embodiment, the Z-reset mold layer 930 (which may also be referred to as a first mold layer) may be formed with any molding process. The first mold layer 930 may comprise an epoxy material or any other suitable electrically insulating material. In an embodiment, the first mold layer 930 may be formed to a thickness that fully embeds the pillars 931A and 931B. That is, the top surfaces of the pillars 931A and 931B and the sidewall surfaces of the pillars 931A and 931B may be covered by the first mold layer 930.

Referring now to FIG. 9D, a cross-sectional illustration of the electronic package 900 after the first mold layer 930 is recessed is shown, in accordance with an embodiment. In an embodiment, the first mold layer 930 may be recessed with a polishing or grinding process, such as a CMP process or the like. In an embodiment, the first mold layer 930 is recessed so that the top surfaces of the pillars 931A and 931B are exposed and substantially coplanar with each other. The polishing process may result in the first mold layer 930 having a substantially flat surface.

Referring now to FIG. 9E, a cross-sectional illustration of the electronic package 900 after pillars 939 are formed over the pillars 931A is shown, in accordance with an embodiment. In the illustrated embodiment, the pillars 931A have a width that is substantially equal to a width of the pillars 939. That is, the combination of the pillars 931A and the pillars 939 may appear as a single continuous structure. Though, in other embodiments, the pillars 939 may have a width that is different than a width of the pillars 931A. For example, the pillars 939 may be narrower than the pillars 931A. Additionally, while shown as being perfectly aligned in FIG. 9E, embodiments may include the pillars 939 being offset from the pillars 931A. In an embodiment, the pillars 939 may be formed with an electroplating process, or mounted to the top surface of the pillars 931A (e.g., with a solder or the like).

Referring now to FIG. 9F, a cross-sectional illustration of the electronic package 900 after a component 925 is coupled to the pillars 931B and a mold extension layer 940 (which may also be referred to as a second mold layer) is formed is shown, in accordance with an embodiment. In an embodiment, the component 925 may comprise a bridge device. For example, the component 925 may comprise one or more routing layers (e.g., indicated as the horizontal rectangles) that allows for lateral electrical routing. In an embodiment, the component 925 may comprise pads that are electrically coupled to pads that are formed over the pillars 931B by interconnects (e.g., solder bumps). The formation of the recessed first mold layer 930 allows for improved Z-positional uniformity between the pads over the pillars 931B. As such, the pitch can be reduced since smaller solder interconnects are able to be used since there is lower Z-height variation. Though, in other embodiments, the interconnects to the component 925 may land directly on the pillars 931B and the pads on the first mold layer 930 may be omitted.

In an embodiment, component pillars 938 may extend up from the routing layer, and the component pillars 938 may be embedded in a mold layer (not shown). In other embodiments, the pillars 938 may be embedded in the second mold layer 940 instead of the a dedicated component mold layer.

While the component 925 is shown as being a bridge in FIG. 9F, embodiments may include any type of component that is useful for the electronic package 900. For example, the component 925 may comprise a passive component (e.g., an inductor, a capacitor, or the like), a memory device, a transistor-based device, and/or the like. Further, while a single component 925 is shown in FIG. 9F, embodiments may comprise any number of components 925.

In an embodiment, the second mold layer 940 may be formed with any molding process. The second mold layer 940 may comprise an epoxy material or any other suitable electrically insulating material. In an embodiment, the second mold layer 940 may be formed to a thickness that fully embeds the pillars 939 and 938. That is, the top surfaces of the pillars 939 and 938 and the sidewall surfaces of the pillars 939 and 938 may be covered by the second mold layer 940. In an embodiment, the first mold layer 930 and the second mold layer 940 may have similar material compositions. In such an embodiment, the first mold layer 930 and the second mold layer 940 may appear as a single layer. Though, in other embodiments, the first mold layer 930 and the second mold layer 940 may comprise different material compositions.

Referring now to FIG. 9G, a cross-sectional illustration of the electronic package 900 after the second mold layer 940 is recessed is shown, in accordance with an embodiment. In an embodiment, the second mold layer 940 may be recessed with a polishing or grinding process, such as a CMP process or the like. In an embodiment, the second mold layer 940 is recessed so that the top surfaces of the pillars 939 and 938 are exposed and substantially coplanar with each other. The polishing process may result in the second mold layer 940 having a substantially flat surface.

Referring now to FIG. 9H, a cross-sectional illustration of the electronic package 900 after interconnects 906A and 906B are electrically coupled to the pillars 939 and 938, respectively, and dies 905 are coupled to the interconnects 906A and 906B is shown, in accordance with an embodiment. In an embodiment, the interconnects 906A and 906B may comprise solder bumps or the like. As shown, the interconnects 906A over the pillars 939 may have a first diameter, and the interconnects 906B over the component 925 pillars may have a second (smaller) diameter. Though, in other embodiments the diameters may be the same.

In an embodiment, the dies 905 may be any type of die, such as a processor, a memory die, a communications die, and/or the like. In some embodiments, a capillary underfill 928 may be provided around and/or under the dies 905. In the case of a panel level assembly, the panel may be singulated into individual units prior to mounting the dies 905 to the package substrate 910.

Referring now to FIG. 9I, a process flow diagram that describes a process 980 for forming an electronic package with a Z-reset mold layer and a mold extension layer is shown, in accordance with an embodiment. In an embodiment, the process 980 may be similar to the process described above with respect to FIGS. 9A – 9H. In an embodiment, the process 980 may begin with operation 981, which comprises forming first pillars on pads on a surface of a substrate. In an embodiment, the first pillars may be high aspect ratio pillars that are formed with an electroplating process or the like. In an embodiment, the substrate may be a package substrate (e.g., with an organic core or a glass core). In some embodiments, the first pillars may comprise a first subgroup with a first diameter and a second subgroup with a second diameter that is different than the first diameter.

In an embodiment, the process 980 may continue with operation 982, which comprises forming a first mold layer (e.g., a Z-reset mold layer) over the surface of the substrate that fully embeds the first pillars. In an embodiment, the first mold layer may be an epoxy based material, a buildup film or the like.

In an embodiment, the process 980 may continue with operation 983, which comprises recessing the first mold layer to expose the first pillars. For example, a CMP process or the like may be used to recess the first mold layer. In some embodiments, the recessing process may remove portions of the first pillars. The recessed surface of the first mold layer may be substantially flat. As such, any Z-height variation of the substrate may be substantially eliminated.

In an embodiment, the process 980 may continue with operation 984, which comprises forming second pillars over the first subgroup of the first pillars. In an embodiment, the second pillars may have a diameter that is different than the diameter of the first subgroup of first pillars, or the second pillars may have substantially the same diameter as the diameter of the first subgroup of first pillars.

In an embodiment, the process 980 may continue with operation 985, which comprises mounting a component, such as a chiplet, a bridge, or the like, to the first mold layer. In an embodiment, the component may comprise third pillars. The third pillars may be embedded in a layer, such as an epoxy mold layer, or the third pillars may be free standing without a surrounding mold layer.

In an embodiment, the process 980 may continue with operation 986, which comprises forming a second mold layer (e.g., a mold extension layer) over the first mold layer that fully embeds the second pillars and the third pillars. In an embodiment, the second mold layer may be an epoxy based material, a buildup film or the like.

In an embodiment, the process 980 may continue with operation 987, which comprises recessing the second mold layer to expose the second pillars and the third pillars. For example, a CMP process or the like may be used to recess the second mold layer. In some embodiments, the recessing process may remove portions of the second pillars and the third pillars. The recessed surface of the second mold layer may be substantially flat. As such, any Z-height variation of the substrate may be substantially eliminated.

In an embodiment, the process 980 may continue with operation 988, which comprises electrically coupling a die to the second pillars and the third pillars of the component. For example, the die may be mounted to first pads over the second pillars and to second pads over the third pillars of the component with interconnects, such as solder balls or the like. Due to the improved pitch scaling, embodiments allow for increased interconnect density between the die and the substrate.

The push towards HPC products (such as GPU and HBM accelerator products or data center CPU products) is driving larger chip complex sizes. For example, large package sizes (e.g., 120mm x 120mm) and high package substrate layer counts (e.g., twenty or more layers) are becoming more common. This leads to low yields and high costs for such advanced package substrates. Accordingly, there is a need for package disaggregation of such products. One solution for package disaggregation relies on package-to-package (P2P) interconnect bridges between two neighboring packages. In existing solutions, topside P2P bridges with about a 300µm bump pitch (or, BGA ball pitch) is desired to provide reasonable bandwidths between the packages. However, the corresponding P2P pads on the GPU (or CPU) packages have issues relating solder attachment of the P2P bridge at such pitches.

One issue is the X-direction and Y-direction positional tolerance of P2P pads on a given package with respect to motherboard (e.g., the BGA pad on the bottom side of the package substrate). For high layer count package substrates, the current tolerance is approximately 100µm or more for each package substrate. Additionally, the Z-direction positional tolerance of the P2P pads between the two neighboring package substrates may be greater than approximately 150µm. These poor X,Y, and Z tolerances for P2P pads on the two ends of the P2P interconnect bridge drives complex P2P bridge configurations. For example, the P2P interconnect bridge may need to be flexible, and alignment pin structures may be necessary to account for X-direction, Y-direction, and Z-direction tolerances. A weighted reflow process may also be needed in some embodiments.

Accordingly, embodiments disclosed herein may include package substrates with P2P pads and mold layers that correct X, Y, and/or Z tolerances in order to simplify P2P interconnect bridge architectures and bonding solutions. In an embodiment, panel level backside mold layers with embedded pillars may be used to reset the Z-height of neighboring packages to a fixed achievable target value. For example, the pillars and the mold layer may be polished in order to achieve a desired Z-height target for the BGA pad. Additionally, the X and/or Y positional tolerances of the large BGA pads with respect to the topside P2P pads can be improved by correcting their X,Y placement with respect to the pillars. The larger BGA pad CD compared to the pillar CD, can enable approximately 100µm or more of X and/or Y positional correction.

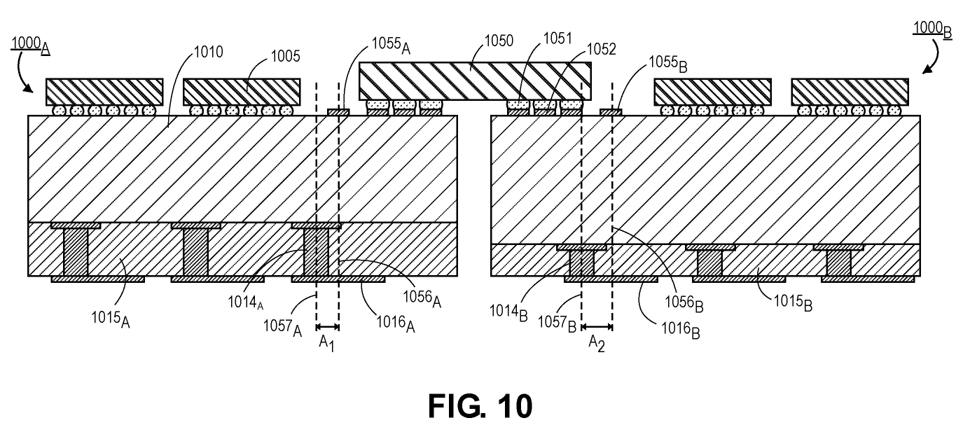

Referring now to FIG. 10, a cross-sectional illustration of a first electronic package 1000A and a second electronic package 1000B that are electrically coupled to each other by a P2P bridge 1050 is shown, in accordance with an embodiment.

As shown, each electronic package 1000A and 1000B may comprise a package substrate 1010 with a corresponding mold layer 1015A and 1015B. In an embodiment, the heights of the mold layer 1015A and 1015B may be different. The different heights can be tuned by a polishing process in order to set total package substrate 1010 heights that are substantially equal to each other. In an embodiment the thickness of the mold layers 1015A and 1015B may be controlled to achieve a fixed Z-height target along with a lower tolerance of approximately 20µm or less across all substrate panels for a given product. This enables a Z-height reset for all packages within the panel and from panel to panel. In an embodiment, pillars 1014A and 1014B may be embedded in each of the mold layers 1015A and 1015B, respectively.

In an embodiment, the X and/or Y position tolerance of the BGA pads 1016A and 1061B may be corrected by placing the BGA pad with respect to the P2P pads 1052 on the topside of the package substrate. The alignment error correction of the backside BGA pads 1016A and 1016B may be implemented by referencing topside fiducials 1055A and 1055B. In an embodiment, the P2P pads 1052 may be between the fiducial 1055 and an edge of the package substrate 1010. In some embodiments, the alignment may be implemented through the use of a data feed forward process and/or by transferring the topside package substrate 1010 location information to the backside of the package substrate 1010 by laser marking features (not shown) on the backside of the package substrate 1010. In some embodiments, such a transfer of alignment features may be done prior to BGA pad lithography mask repositioning.

As shown, the fiducials 1055A and/or 1055B may share a substantially common centerline 1056A and/or 1056B with the BGA pads 1016A and/or 1016B. Additionally, the repositioning of the BGA pads 1016A and/or 1016B may result in the centerlines 1056A and/or 1056B of the BGA pads 1016A and/or 1016B being offset be a distance A1 and/or A2 from centerlines 1057A and/or 1057B of the corresponding pillars 1014A and/or 1014B.

In an embodiment, the improved X, Y, and/or Z positional alignment allows for simpler P2P bridge 1050 design and integration. For example, a stiff bridge (e.g., silicon, glass, or the like) may be coupled to the P2P pads 1052 with solder interconnects 1051 or the like. Such embodiments may allow for pitch scaling of the interconnects 1051, which allows for improved data transfer bandwidths between the electronic packages 1000A and 1000B.

In an embodiment, one or more dies 1005 may be coupled to each of the package substrates 1010. In an embodiment, the dies 1005 may comprise any type of die, such as a processor (e.g., a central processing unit (CPU), a graphics processing unit (GPU), an XPU, or the like), a memory die (e.g., a HBM), a communications die, or the like. While a pair of dies 1005 are shown on each package substrate 1010 in FIG. 10, it is to be appreciated that any number of dies 1005 may be coupled to each of the package substrates 1010.

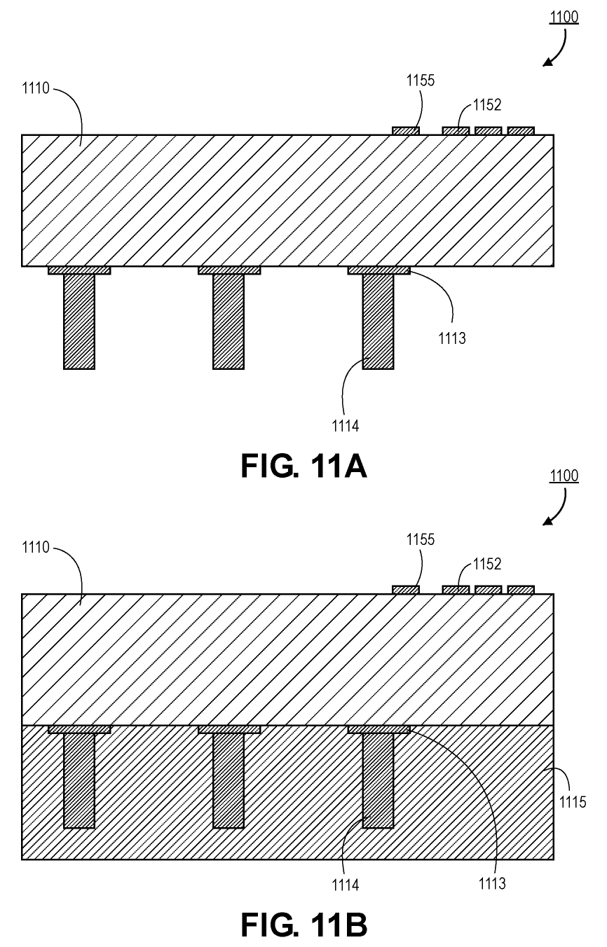

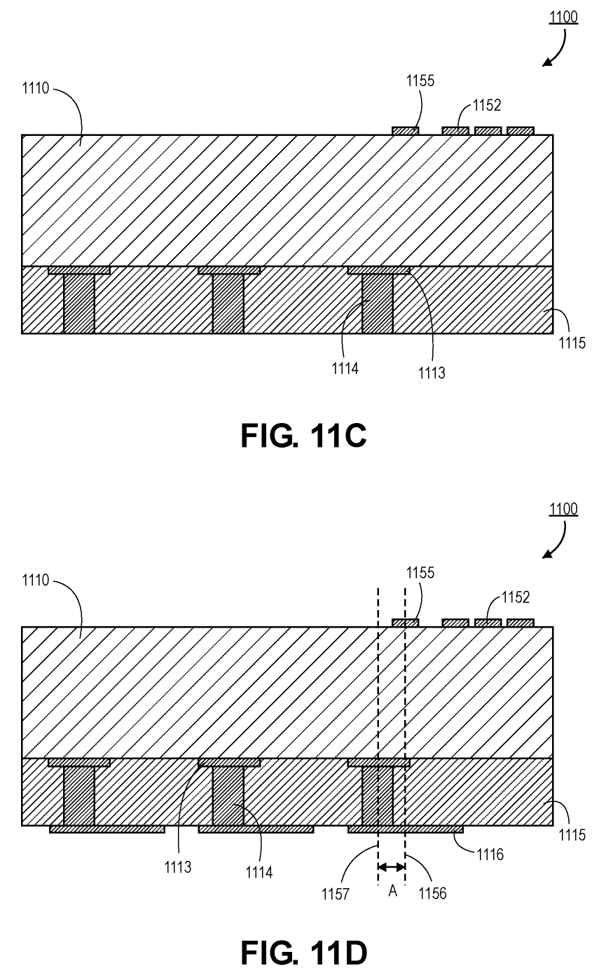

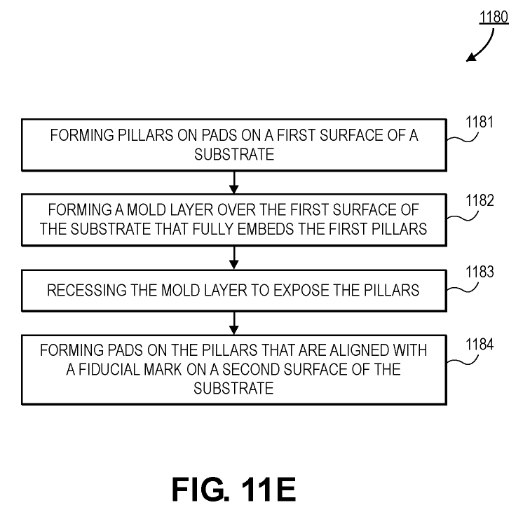

Referring now to FIGS. 11A – 11D, a series of cross-sectional illustrations depicting a process for forming an electronic package 1100 for use with P2Pinterconnects that comprises a mold layer 1115 under the package substrate 1110 and precisely aligned BGA pads 1116 is shown, in accordance with an embodiment. In an embodiment, the mold layer 1115 sets the total thickness of the electronic package 1100 and improves thickness variation across the package substrate 1110. The precisely aligned BGA pads 1116 allow for improved X and Y positional tolerances used to couple the package substrate 1110 to an underlying board. As such, the interconnect bridge between electronic packages 1100 may have higher density interconnects with simplified manufacturing and/or assembly processes.

Referring now to FIG. 11A, a cross-sectional illustration of an electronic package 1100 at a stage of manufacture is shown, in accordance with an embodiment. In an embodiment, the electronic package 1100 may comprise a package substrate 1110. The package substrate 1110 may be similar to any of the package substrates described in greater detail herein. For example, the package substrate 1110 may comprise a core (e.g., a glass core or an organic core) with organic dielectric buildup layers over and/or under the core. In an embodiment, P2P pads 1152 may be formed on a top surface of the package substrate 1110. In an embodiment, a fiducial 1155 may also be formed on the top surface of the package substrate 1110.

In an embodiment, pads 1113 may be formed on a bottom surface of the package substrate 1110. In an embodiment, pillars 1114 may be electrically coupled to the pads 1113. In an embodiment, the pillars 1114 may be similar to any of the pillars described in greater detail herein. For example, the pillars may be high aspect ratio electrically conductive pillars (e.g., copper pillars) that are plated up from the pads 1113 or mounted to the pads 1113 (e.g., with a solder or the like).

Referring now to FIG. 11B, a cross-sectional illustration of the electronic package 1100 after a mold layer 1115 is formed over the package substrate 1110 is shown, in accordance with an embodiment. In an embodiment, the mold layer 1115 may be formed with any molding process. The mold layer 1115 may comprise an epoxy material or any other suitable electrically insulating material. In an embodiment, the mold layer 1115 may be formed to a thickness that fully embeds the pillars 1114. That is, the top surfaces of the pillars 1114 and the sidewall surfaces of the pillars 1114 may be covered by the mold layer 1115.

Referring now to FIG. 11C, a cross-sectional illustration of the electronic package 1100 after the mold layer 1115 is recessed is shown, in accordance with an embodiment. In an embodiment, the mold layer 1115 may be recessed with a polishing or grinding process, such as a CMP process or the like. In an embodiment, the mold layer 1115 is recessed so that the top surfaces of the pillars 1114 are exposed and substantially coplanar with each other. The polishing process may result in the mold layer 1115 having a substantially flat surface with a precisely controlled thickness.

Referring now to FIG. 11D, a cross-sectional illustration of the electronic package 1100 after BGA pads 1116 are formed over the pillars 1114. A width of the BGA pads 1116 may be greater than a width of the fiducial 1155 and/or the P2P pads 1152. In an embodiment, lithography used to form the BGA pads 1116 is informed by the placement of a fiducial 1155 on an opposite side of the package substrate 1110. In an embodiment, the alignment may be implemented through the use of a data feed forward process and/or by transferring the topside package substrate 1110 location information to the backside of the package substrate 1110 by laser marking features (not shown) on the backside of the package substrate 1110. In some embodiments, such a transfer of alignment features may be done prior to BGA pad 1116 lithography mask repositioning.

As shown, the alignment process results in a centerline 1156 of the fiducial 1155 and the BGA pads 1116 that are substantially aligned. For example, the BGA pad 1116 and the fiducial 1155 may have aligned centerlines (e.g., substantially common centerlines that are within 20µm of each other). Due to the need to align the BGA pads 1116 with the fiducial 1155, the pillar 1114 the corresponding BGA pad 1116 may be offset from each other. For example, a centerline 1156 of the BGA pad 1116 may be offset by a distance A from the centerline 1157 of the pillar 1114.

Referring now to FIG. 11E, a process flow diagram depicting a process 1180 for forming an electronic package with a mold layer and precisely aligned BGA pads to enable P2P interconnects is shown, in accordance with an embodiment. In an embodiment, the process 1180 may continue with operation 1181, which comprises forming pillars on pads on a first surface of a substrate. In an embodiment, the substrate may be a package substrate similar to any of the package substrates described in greater detail herein. The pillars may be high aspect ratio pillars that are plated up from the pad or otherwise coupled to the pads.

In an embodiment, the process 1180 may continue with operation 1182, which comprises forming a mold layer over the first surface of the substrate that fully embeds the first pillars. In an embodiment, the mold layer may be similar to any of the mold layers described in greater detail herein. For example, the mold layer may comprise an epoxy or the like.

In an embodiment, the process 1180 may continue with operation 1183, which comprises recessing the mold layer to expose the pillars. For example, a CMP process or the like may be used to recess the mold layer. In some embodiments, the recessing process may remove portions of the pillars. The recessed surface of the mold layer may be substantially flat. As such, any Z-height variation of the substrate may be substantially eliminated, and/or a total height of the electronic package 1100 may be precisely set.

In an embodiment, the process 1180 may continue with operation 1184, which comprises forming pads on the pillars. In an embodiment, the pillars may be aligned with a fiducial mark on a second surface of the substrate. In an embodiment, a centerline of the fiducial mark may be substantially centered with a centerline with one of the pads on the pillars. For example, the alignment may be implemented through the use of a data feed forward process and/or by transferring the second surface of the substrate location information to the first surface of the substrate by laser marking features on the first surface of the package substrate 1110. In some embodiments, such a transfer of alignment features may be done prior to pad lithography mask repositioning for the formation of the substrate. In an embodiment, the pads may be BGA pads used to electrically coupled the substrate to an underlying board or the like.

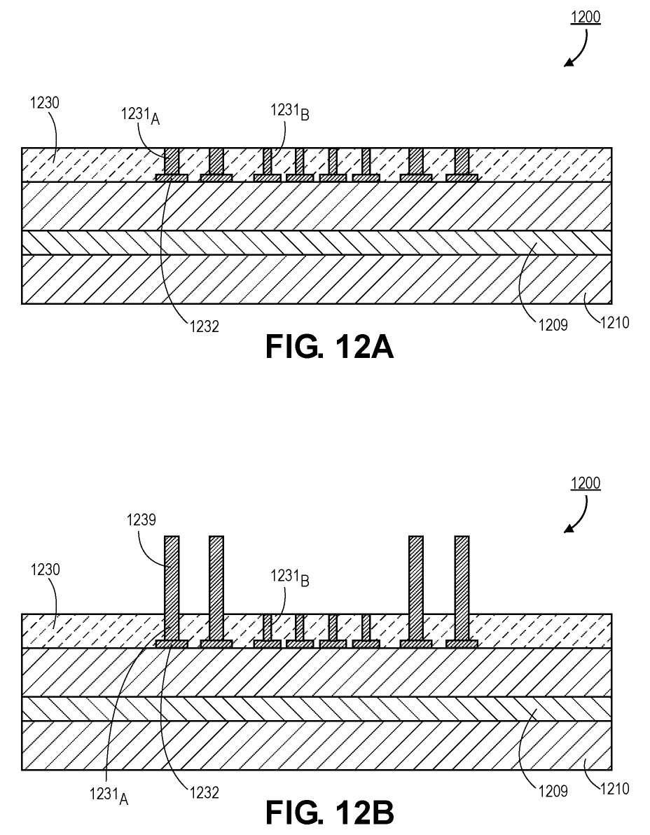

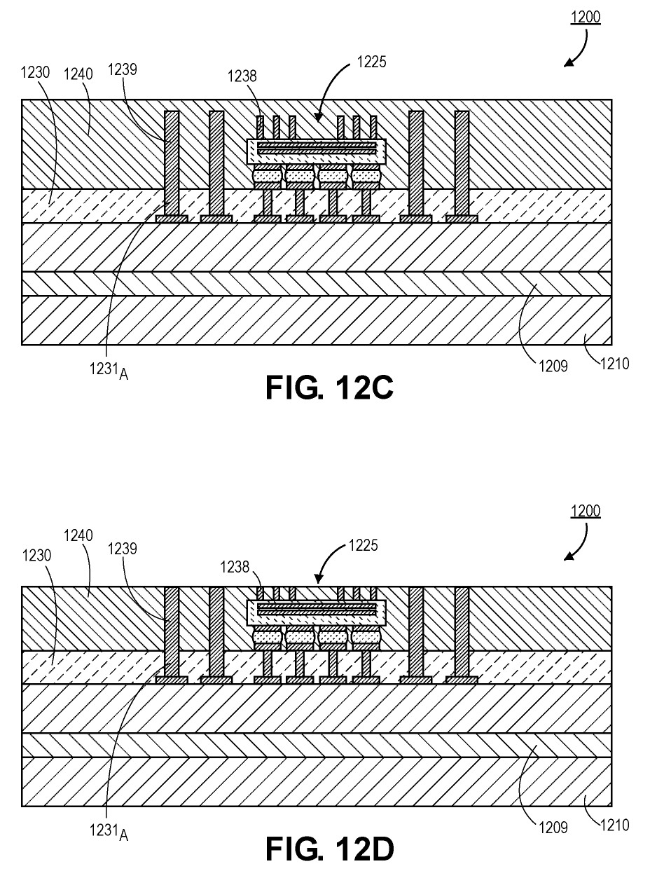

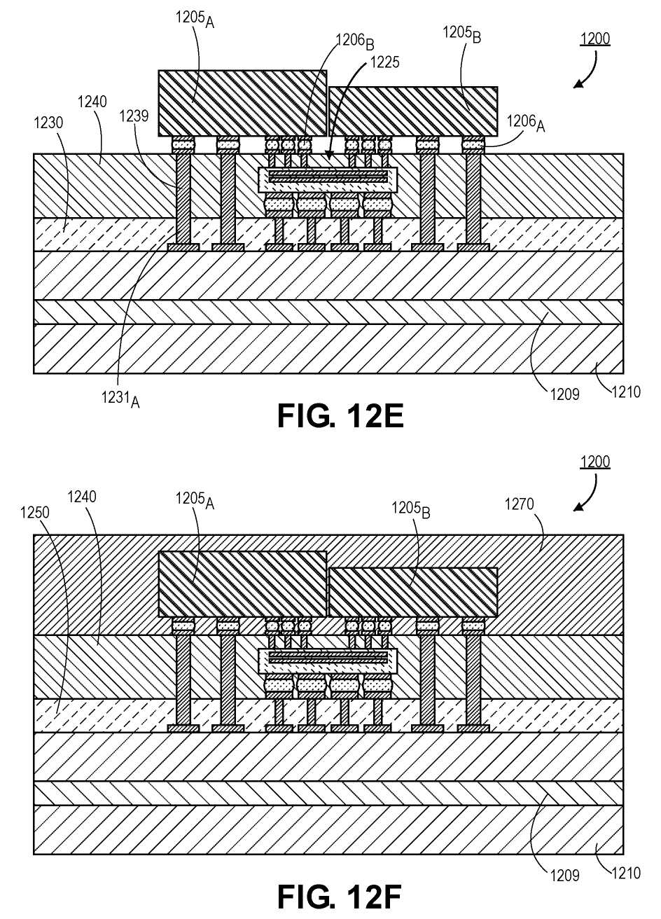

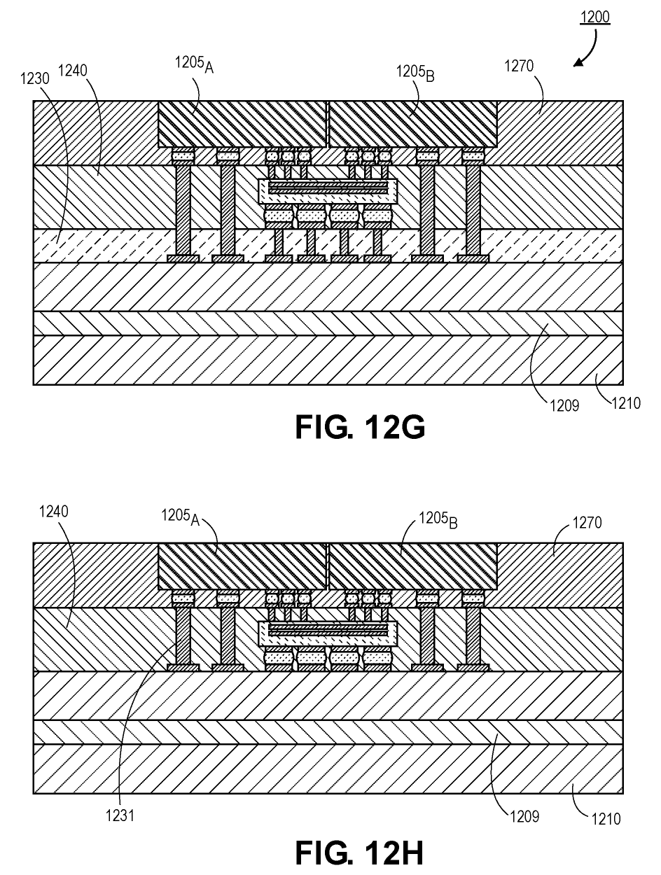

As described in other embodiments herein, bridge-based electronic packages may use singulated package substrates for top die assembly. As such, the top dies are difficult to mold and planarize. This may result in a skyline of the electronic package that is non-uniform. This nonplanar skyline may result in poor thermal contact to a system thermal solution. In the previous embodiments, the integration of the components, such as interconnect bridges, on a panel level process using a mold extension layer has been described. The improved Z-height uniformity from such mold extension layers allows for finer pitched interconnects. However, the skyline may still be non-uniform due to variations in die thickness. Accordingly, embodiments disclosed herein may further extend the panel level processing to attach, mold, and planarize the top dies. Such processes may enable the mold layer extension to further provide a planar skyline for the top dies. As such, molding processes and/or the integration of thermal solutions may be improved. FIGS. 12A – 12H are examples of embodiments that include such a process.

Referring now to FIG. 12A, a cross-sectional illustration of an electronic package 1200 at a stage of manufacture is shown, in accordance with an embodiment. In an embodiment, the electronic package 1200 comprises a package substrate 1210. In an embodiment, the package substrate 1210 may be similar to any of the package substrates described in greater detail herein. For example, the package substrate 1210 may comprise a core 1209 (e.g., a glass core or an organic core) with buildup layers over and/or under the core 1209.

In an embodiment, the electronic package 1200 may further comprise a Z-reset mold layer 1230 (which may be referred to herein as a first mold layer). In an embodiment, the first mold layer 1230 may comprise first pillars 1231A and 1231B that are provided over pads 1232. The first mold layer 1230 and the first pillars 1231A and 1231B may be formed with processes similar to any of those described in greater detail herein. For example, high aspect ratio first pillars 1231 may be formed on the pads 1232, a mold layer 1230 may be formed to fully embed the first pillars 1231, and the mold layer 1230 may be recessed to expose the top surfaces of the first pillars 1231.

Referring now to FIG. 12B, a cross-sectional illustration of the electronic package 1200 after second pillars 1239 are formed over the first pillars 1231A is shown, in accordance with an embodiment. In the illustrated embodiment, the first pillars 1231A have a width that is substantially equal to a width of the second pillars 1239. That is, the combination of the first pillars 1231A and the second pillars 1239 may appear as a single continuous structure. Though, in other embodiments, the second pillars 1239 may have a width that is different than a width of the first pillars 1231A. For example, the second pillars 1239 may be narrower than the first pillars 1231A. Additionally, while shown as being perfectly aligned in FIG. 12B, embodiments may include the pillars 1239 being offset from the pillars 1231A. In an embodiment, the second pillars 1239 may be formed with an electroplating process, or mounted to the top surface of the first pillars 1231A (e.g., with a solder or the like).

Referring now to FIG. 12C, a cross-sectional illustration of the electronic package 1200 after a component 1225 is coupled to the first pillars 1231B and a mold extension layer 1240 (which may also be referred to as a second mold layer) is formed is shown, in accordance with an embodiment. In an embodiment, the component 1225 may comprise a bridge device. For example, the component 1225 may comprise one or more routing layers (e.g., indicated as the horizontal rectangles) that allows for lateral electrical routing. In an embodiment, the component 1225 may comprise pads that are electrically coupled to pads that are formed over the first pillars 1231B by interconnects, such as solder bumps. The formation of the recessed first mold layer 1230 allows for improved Z-positional uniformity between the pads over the first pillars 1231B. As such, the pitch of the interconnects can be reduced since smaller solder interconnects are able to be used since there is lower Z-height variation. Though, in other embodiments, the interconnects to the component 1225 may land directly on the first pillars 1231B and the pads on the first mold layer 1230 may be omitted.

In an embodiment, component pillars 1238 may extend up from the routing layer, and the component pillars 1238 may be embedded in a mold layer (not shown). In other embodiments, the component pillars 1238 may be embedded in the second mold layer 1240 instead of the a dedicated component mold layer.

While the component 1225 is shown as being a bridge in FIG. 12C, embodiments may include any type of component that is useful for the electronic package 1200. For example, the component 1225 may comprise a passive component (e.g., an inductor, a capacitor, or the like), a memory device, a transistor-based device, and/or the like. Further, while a single component 1225 is shown in FIG. 12C, embodiments may comprise any number of components 1225.

In an embodiment, the second mold layer 1240 may be formed with any molding process. The second mold layer 1240 may comprise an epoxy material or any other suitable electrically insulating material. In an embodiment, the second mold layer 1240 may be formed to a thickness that fully embeds the second pillars 1239 and the component pillars 1238. That is, the top surfaces of the second pillars 1239 and the component pillars 1238 and the sidewall surfaces of the second pillars 1239 and the component pillars 1238 may be covered by the second mold layer 1240. In an embodiment, the first mold layer 1230 and the second mold layer 1240 may have similar material compositions. In such an embodiment, the first mold layer 1230 and the second mold layer 1240 may appear as a single layer. Though, in other embodiments, the first mold layer 1230 and the second mold layer 1240 may comprise different material compositions.

Referring now to FIG. 12D, a cross-sectional illustration of the electronic package 1200 after the second mold layer 1240 is recessed is shown, in accordance with an embodiment. In an embodiment, the second mold layer 1240 may be recessed with a polishing or grinding process, such as a CMP process or the like. In an embodiment, the second mold layer 1240 is recessed so that the top surfaces of the second pillars 1239 and the component pillars 1238 are exposed and substantially coplanar with each other. The polishing process may result in the second mold layer 1240 having a substantially flat surface.

Referring now to FIG. 12E, a cross-sectional illustration of the electronic package 1200 after dies 1205A and 1205B are mounted to the second mold layer 1240 is shown, in accordance with an embodiment. For example, pads may be formed on the second pillars 1239 and the component pillars 1238, and interconnects 1206A and 1206B may electrically couple these pads to the dies 1205A and 1205B. In an embodiment, the dies may be any type of die, such as any of the types of dies described in greater detail herein. In an embodiment, the dies 1205A and 1205B may have different thicknesses. As such, the electronic package 1200 does not have a flat skyline at this point in the process flow.

Referring now to FIG. 12F, a cross-sectional illustration of the electronic package 1200 after a third mold layer 1270 is formed over the dies 1205A and 1205B. In the illustrated embodiment, the mold layer 1270 underfills the dies 1205A and 1205B. Though, in other embodiments, a capillary underfill or the like may be provided under the dies 1205A and 1205B. In an embodiment, the third mold layer 1270 may have a thickness so that the dies 1205A and 1205B are fully embedded by the third mold layer 1270.

Referring now to FIG. 12G, a cross-sectional illustration of the electronic package 1200 after the third mold layer 1270 is recessed is shown, in accordance with an embodiment. In an embodiment, the third mold layer 1270 may be recessed with a CMP process or the like. In an embodiment, the recessing process may also result in polishing or grinding backside surfaces of the dies 1205A and 1205B. As such, the skyline of the electronic package 1200 is flattened. This allows for improved thermal control since thermal solutions can provide better thermal coupling with the dies 1205A and 1205B.

Referring now to FIG. 12H, a cross-sectional illustration of an electronic package 1200 is shown, in accordance with an additional embodiment. As shown, the electronic package 1200 in FIG. 12H may be similar to the electronic package 1200 in FIG. 12G, with the exception of the removal of the first mold layer 1230. As shown, the second mold layer 1240 may be formed directly over the top surface of the package substrate 1210. That is, there may not be pillars between the component 1225 and the package substrate 1210.

Referring now to FIG. 12I, a flow diagram of a process 1280 for forming an electronic system with a planarized die overmold layer for improved flatness of the skyline is shown, in accordance with an embodiment. In an embodiment, the process 1280 may be similar to the process described above with respect to FIGS. 12A – 12H. In an embodiment, the process 1280 may begin with operation 1281, which comprises forming first pillars on a surface of a substrate. In an embodiment, the pillars may be high aspect ratio pillars that are formed with an electroplating process or the like. In an embodiment, the substrate may be a package substrate (e.g., with an organic core or a glass core).

In an embodiment, the process 1280 may continue with operation 1282, which comprises mounting a component, such as a chiplet, a bridge, or the like, to the surface of the substrate. In an embodiment, the component may comprise component pillars. The component pillars may be embedded in a layer, such as an epoxy mold layer.

In an embodiment, the process 1280 may continue with operation 1283, which comprises forming a first mold layer over the substrate that fully embeds the pillars and the component pillars. In an embodiment, the first mold layer may be an epoxy based material, a buildup film or the like.

In an embodiment, the process 1280 may continue with operation 1284, which comprises recessing the first mold layer to expose the pillars and the component pillars. For example, a CMP process or the like may be used to recess the first mold layer. In some embodiments, the recessing process may remove portions of the pillars and/or the component pillars. The recessed surface of first the mold layer may be substantially flat. As such, any Z-height variation of the substrate may be substantially eliminated.

In an embodiment, the process 1280 may continue with operation 1285, which comprises attaching a die to the pillars and the component pillars. In an embodiment, pads may be formed on the pillars and the component pillars with a single patterning process. As such, any X-direction and/or Y-direction position variation is substantially eliminated. The removal of position variation in the X, Y, and Z direction allows for improved pitch scaling. In an embodiment, interconnects may electrically couple the die to the pillars and the component pillars.

In an embodiment, the process 1280 may continue with operation 1286, which comprises forming a second mold layer over the first mold layer. In an embodiment, the second mold layer embeds the die. The second mold layer may be similar to the first mold layer. Though, different materials may be used for the first mold layer and the second mold layer in other embodiments.

In an embodiment, the process 1280 may continue with operation 1287, which comprises recessing the second mold layer to expose a backside of the die. In an embodiment, the backside of the recessing process may include the use of a CMP process or the like. In the case of multiple dies, the plurality of dies may be planarized to have a substantially planar surface which is more beneficial for thermally coupling the dies to a heatsink or other temperature control systems.

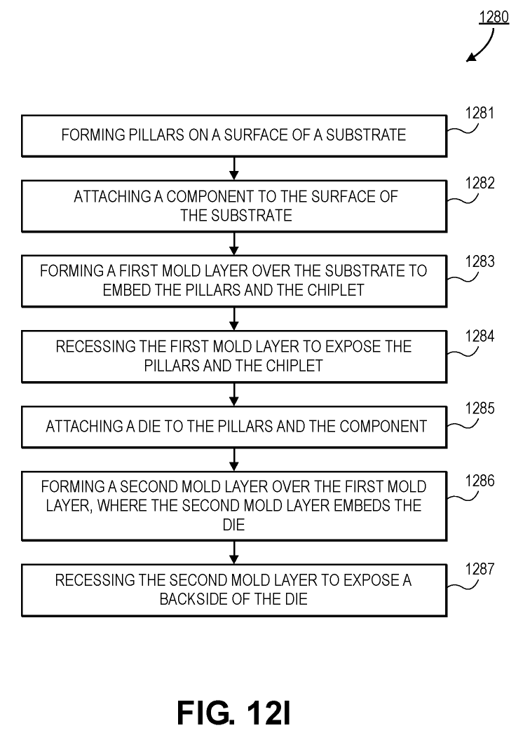

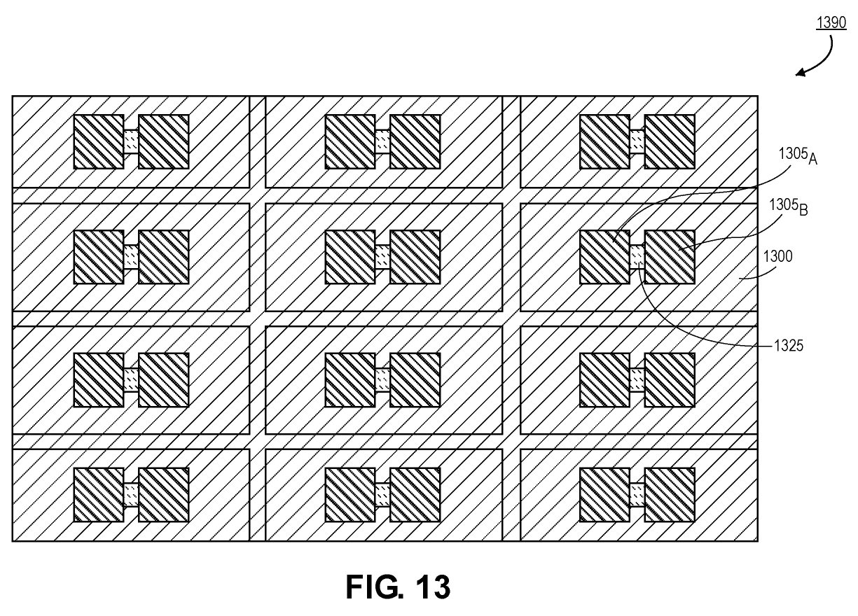

As noted in various embodiments described herein, the process flows used to manufacture various electronic packages may be implemented at a panel level, a quarter-panel level, a unit level, or the like. For example, the various mold layers described herein may be formed at larger form factors, such as the panel form factor. FIG. 13 is a plan view illustration of a panel 1390 that may be used to form a plurality of electronic packages 1300.

In FIG. 13, a plurality of electronic packages 1300 are arranged across the panel 1390. In an embodiment, the individual electronic packages 1300 may be spaced apart from each other by saw streets or the like. In an embodiment, the individual electronic packages 1300 may be similar to any of the electronic packages described in greater detail herein. In an embodiment, the electronic packages 1300 may be formed on a common package substrate that has the panel 1390 form factor. The common package substrate may be similar to any of the package substrates described in greater detail herein. For example, the package substrate may comprise a glass core or an organic core with dielectric buildup layers over and/or under the core. In an embodiment, one or more mold layers with embedded electrically conductive pillars may be provided over and/or under the common package substrate.

As shown, one or more dies 1305A and 1305B may be electrically coupled to the common package substrate in each of the electronic packages 1300. In some embodiments, a component 1325 may be embedded in a mold layer below the one or more dies 1305A and 1305B. In the illustrated embodiment, the component 1325 may comprise a bridge die that electrically couples the dies 1305A and 1305B together.

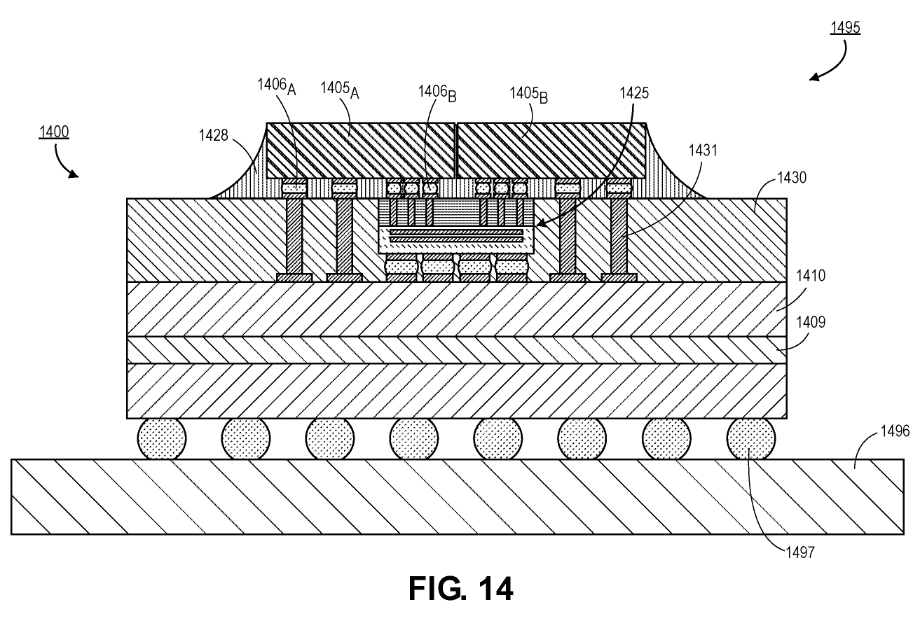

Referring now to FIG. 14, a cross-sectional illustration of an electronic system 1495 is shown, in accordance with an embodiment. In an embodiment, the electronic system 1495 may comprise an electronic package 1400 that is electrically coupled to a board 1496 (e.g., a motherboard, a printed circuit board (PCB), or the like) by interconnects 1497, such as BGA solder balls. In an embodiment, the electronic package 1400 may be similar to any of the electronic packages disclosed in greater detail herein. For example, the electronic package 1400 may comprise a package substrate 1410 with a core 1409 and one or more mold layers 1430 with embedded pillars 1431. A component 1425 may also be embedded within the mold layer 1430. The component 1425 may be electrically coupled to the package substrate 1410 by interconnects, such as solder balls and/or by pillars (not shown in FIG. 14) that are embedded in a mold layer 1430.

In an embodiment, one or more dies 1405A and 1405B may be electrically coupled to the pillars 1431 and/or the component 1425 by interconnects 1406A and/or 1406B. A capillary underfill 1428 may surround portions of the dies 1405A and/or 1405B. In some embodiments, a mold layer (not shown) may also embed the dies 1405A and/or 1405B in order to provide a flat skyline for the electronic system 1495.

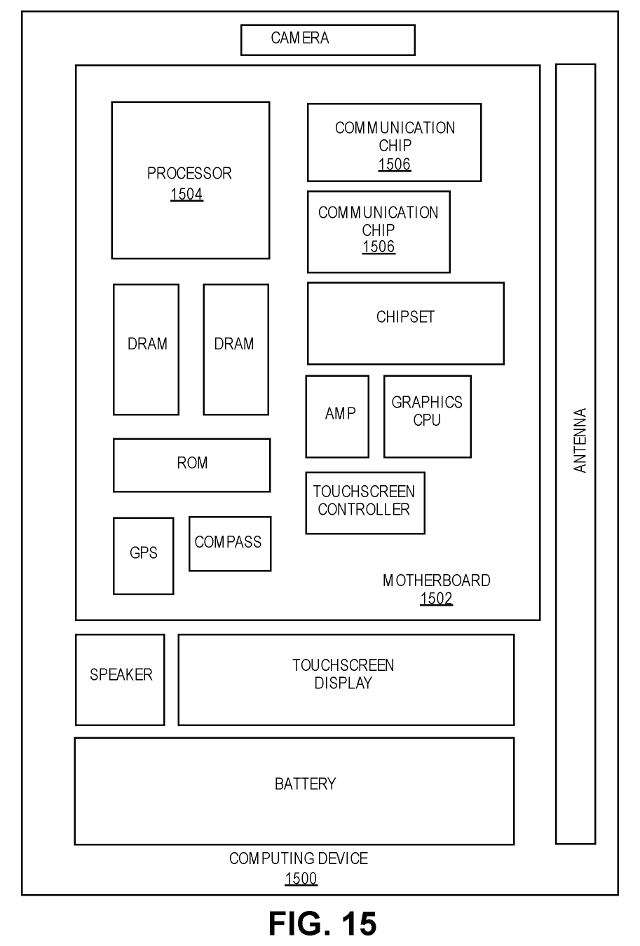

FIG. 15 illustrates a computing device 1500 in accordance with one implementation of the disclosure. The computing device 1500 houses a board 1502. The board 1502 may include a number of components, including but not limited to a processor 1504 and at least one communication chip 1506. The processor 1504 is physically and electrically coupled to the board 1502. In some implementations the at least one communication chip 1506 is also physically and electrically coupled to the board 1502. In further implementations, the communication chip 1506 is part of the processor 1504.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1506 enables wireless communications for the transfer of data to and from the computing device 1500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1500 may include a plurality of communication chips 1506. For instance, a first communication chip 1506 may be dedicated to shorter range wireless communications such as Wi-Fi and Bluetooth and a second communication chip 1506 may be dedicated to longer range wireless communications such as GPS, EDGE, GPRS, CDMA, WiMAX, LTE, Ev-DO, and others.

The processor 1504 of the computing device 1500 includes an integrated circuit die packaged within the processor 1504. In some implementations of the disclosure, the integrated circuit die of the processor may be part of an electronic packaging system that comprises a package substrate with one or more mold layers with embedded pillars to provide flat surfaces to enable enhanced pitch scaling, in accordance with embodiments described herein. The term “processor” may refer to any device or portion of a device that processes electronic data from registers and/or memory to transform that electronic data into other electronic data that may be stored in registers and/or memory.

The communication chip 1506 also includes an integrated circuit die packaged within the communication chip 1506. In accordance with another implementation of the disclosure, the integrated circuit die of the communication chip may be part of an electronic packaging system that comprises a package substrate with one or more mold layers with embedded pillars to provide flat surfaces to enable enhanced pitch scaling, in accordance with embodiments described herein.

In an embodiment, the computing device 1500 may be part of any apparatus. For example, the computing device may be part of a personal computer, a server, a mobile device, a tablet, an automobile, or the like. That is, the computing device 1500 is not limited to being used for any particular type of system, and the computing device 1500 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### Examples

Example 1: an apparatus, comprising: a substrate with a first surface and a second surface opposite from the first surface; a first pillar on the first surface of the substrate; a second pillar on the first surface of the substrate; a first layer over the first surface of the substrate, wherein the first layer embeds the first pillar and the second pillar; a third pillar on the second pillar; a component over the first layer, wherein the component is coupled to the second pillar; and a second layer over the first layer, wherein the second layer embeds the third pillar and the component.

Example 2: the apparatus of Example 1, wherein the component comprises: a routing layer; and a plurality of fourth pillars over the routing layer, and wherein the second layer embeds the plurality of fourth pillars.

Example 3: the apparatus of Example 2, wherein a surface of the third pillar is substantially coplanar with a surface of at least one of the plurality of fourth pillars.

Example 4: the apparatus of Example 2 or Example 3, further comprising: a first die that is coupled to the third pillar and a first one of the plurality of fourth pillars; and a second die that is coupled to a second one of the plurality of fourth pillars.

Example 5: the apparatus of Example 4, wherein the routing layer is coupled the first die to the second die.

Example 6: the apparatus of Examples 1-5, wherein the first layer and the second layer are mold layers.

Example 7: the apparatus of Examples 1-6, wherein the substrate comprises: a core; and an organic dielectric layer over the core.

Example 8: the apparatus of Example 7, wherein the core comprises a glass layer.

Example 9: the apparatus of Examples 1-8, wherein the component is a passive component.

Example 10: the apparatus of Examples 1-9, wherein the component is coupled to the second pillar by a solder bump.

Example 11. A method, comprising: forming a plurality of first pillars on a first surface of a substrate; forming a first mold layer over the substrate, wherein the first mold layer embeds the plurality of first pillars; recessing the first mold layer to expose the plurality of first pillars; forming a plurality of second pillars on corresponding ones of the plurality of first pillars; attaching a component to the first mold layer; forming a second mold layer over the first mold layer, wherein the second mold layer embeds the plurality of second pillars and the component; recessing the second mold layer to expose the plurality of second pillars; and attaching a die to the second mold layer, wherein the die is coupled to the plurality of second pillars and the component.

Example 12: the method of Example 11, wherein the component comprises: a plurality of third pillars, wherein the second mold layer embeds the plurality of third pillars.

Example 13: the method of Example 12, wherein the die is coupled to the component by the plurality of third pillars.

Example 14: the method of Examples 11-13, wherein the first mold layer and the second mold layer comprise substantially similar material compositions.

Example 15: the method of Examples 11-14, wherein the component comprises a routing layer.

Example 16: the method of Examples 11-15, wherein the component is a passive component.

Example 17: the method of Examples 11-16, wherein the substrate is a panel level substrate, and wherein a plurality of devices are fabricated on the panel level substrate substantially in parallel.

Example 18. An apparatus, comprising: a board; a package substrate coupled to the board, wherein the package substrate comprises: a substrate; a first plurality of pillars over a surface of the substrate; a first mold layer around the first plurality of pillars; a second plurality of pillars on the first plurality of pillars; a component on the first mold layer; and a second mold layer around the second plurality of pillars and the component; and a die coupled to the package substrate, wherein the die is coupled to at least one of the first plurality of pillars.

Example 19: the apparatus of Example 18, wherein the component is coupled to the die.

Example 20: the apparatus of Example 19, further comprising: a second die coupled to the package substrate and coupled to the component, and wherein the component is coupled the die to the second die.

What is claimed is:

1. An apparatus, comprising:
a substrate with a first surface and a second surface opposite from the first surface;
a first pillar on the first surface of the substrate;
a second pillar on the first surface of the substrate;
a first layer over the first surface of the substrate, wherein the first layer embeds the first pillar and the second pillar;
a third pillar on the second pillar;
a component over the first layer, wherein the component is coupled to the second pillar; and
a second layer over the first layer, wherein the second layer embeds the third pillar and the component.

2. The apparatus of claim 1, wherein the component comprises:
a routing layer; and
a plurality of fourth pillars over the routing layer, and wherein the second layer embeds the plurality of fourth pillars.

3. The apparatus of claim 2, wherein a surface of the third pillar is substantially coplanar with a surface of at least one of the plurality of fourth pillars.

4. The apparatus of claim 2, further comprising:
a first die that is coupled to the third pillar and a first one of the plurality of fourth pillars; and
a second die that is coupled to a second one of the plurality of fourth pillars.

5. The apparatus of claim 4, wherein the routing layer is coupled to the first die to the second die.

6. The apparatus of claim 1, wherein the first layer and the second layer are mold layers.

7. The apparatus of claim 1, wherein the substrate comprises:
a core; and
an organic dielectric layer over the core.

8. The apparatus of claim 7, wherein the core comprises a glass layer.

9. The apparatus of claim 1, wherein the component is a passive component.

10. The apparatus of claim 1, wherein the component is coupled to the second pillar by a solder bump.

11. A method, comprising:
forming a plurality of first pillars on a first surface of a substrate;
forming a first mold layer over the substrate, wherein the first mold layer embeds the plurality of first pillars;
recessing the first mold layer to expose the plurality of first pillars;
forming a plurality of second pillars on corresponding ones of the plurality of first pillars;
attaching a component to the first mold layer;
forming a second mold layer over the first mold layer, wherein the second mold layer embeds the plurality of second pillars and the component;
recessing the second mold layer to expose the plurality of second pillars; and
attaching a die to the second mold layer, wherein the die is coupled to the plurality of second pillars and the component.

12. The method of claim 11, wherein the component comprises:
a plurality of third pillars, wherein the second mold layer embeds the plurality of third pillars.

13. The method of claim 12, wherein the die is coupled to the component by the plurality of third pillars.

14. The method of claim 11, wherein the first mold layer and the second mold layer comprise substantially similar material compositions.

15. The method of claim 11, wherein the component comprises a routing layer.

16. The method of claim 11, wherein the component is a passive component.

17. The method of claim 11, wherein the substrate is a panel level substrate, and wherein a plurality of devices are fabricated on the panel level substrate substantially in parallel.

18. An apparatus, comprising:
a board;
a package substrate coupled to the board, wherein the package substrate comprises:
a substrate;
a first plurality of pillars over a surface of the substrate;
a first mold layer around the first plurality of pillars;
a second plurality of pillars on the first plurality of pillars;
a component on the first mold layer; and
a second mold layer around the second plurality of pillars and the component; and
a die coupled to the package substrate, wherein the die is coupled to at least one of the first plurality of pillars.

19. The apparatus of claim 18, wherein the component is coupled to the die.

20. The apparatus of claim 19, further comprising:
a second die coupled to the package substrate and coupled to the component, and wherein the component is coupled the die to the second die.
